(19) United States
(12) Patent Application Publication
(10) Pub. No.: US 2015/0014867 A1
(43) Pub. Date: Jan. 15, 2015

(54) RESIN COMPOSITION AND SEMICONDUCTOR DEVICE

(71) Applicant: SUMITOMO BAKELITE CO., LTD., Tokyo (JP)

(72) Inventor: Keiichi Tsukurimichi, Fukuoka (JP)

(73) Assignee: SUMITOMO BAKELITE CO., LTD., Tokyo (JP)

(21) Appl. No.: 14/384,328

(22) PCT Filed: Mar. 14, 2013
(86) PCT No.: PCT/JP2013/001695

§ 371 Date: Sep. 10, 2014

(30) Foreign Application Priority Data
Mar. 29, 2012 (JP) 2012-077658

(51) Int. Cl. H01L 23/29; C08L 63/00; C08K 3/36

(52) U.S. Cl. CPC H01L 23/296; C08K 3/36; C08L 63/00; C08K 2201/003; C08L 2203/206; C08L 2205/025
USPC 257/791; 523/443

(57) ABSTRACT

Provided is a resin composition for encapsulation including: a curing resin; and an inorganic filler, in which the resin composition encapsulates a semiconductor element provided over a substrate and fills a gap between the substrate and the semiconductor element, and when a particle diameter at a cumulative frequency of 5% in order from the largest particle diameter in a volume particle diameter distribution of particles contained in the inorganic filler is represented by Rₘₐₓ (μm), and when a maximum peak diameter in the volume particle diameter distribution of the particles contained in the inorganic filler is represented by R (μm), R<Rₘₐₓ, 1 μm≦R≦24 μm, and R/Rₘₐₓ≧0.45.

### TECHNICAL FIELD

The present invention relates to a resin composition and a semiconductor device.

### BACKGROUND ART

Along with the demand for high performance and reduction in size and weight of recent electronic apparatuses, in semiconductor packages used in these electronic apparatuses, a reduction in size and increase in the number of pins have further progressed compared to the related art.

This semiconductor package includes a circuit substrate and a semiconductor chip (semiconductor element) that is electrically connected onto the circuit substrate through metal bumps, in which the semiconductor chip is encapsulated (coated) with an encapsulant formed of a resin composition. In addition, when the semiconductor chip is encapsulated, the resin composition fills a gap between the circuit substrate and the semiconductor chip for reinforcement (for example, Patent Document 1). By providing such an encapsulant (mold underfill), a highly reliable semiconductor package is obtained.

In addition, the resin composition includes a curing resin and an inorganic filler, and the encapsulant is obtained by molding the resin composition by, for example, transfer molding. Here, in recent semiconductor packages, along with a reduction in size and increase in the number of pins, a pitch of the metal bumps through which the circuit substrate side and the semiconductor chip side are connected are small, and a distance between the substrate and the semiconductor chip is small. Therefore, in order to fill a gap between the substrate and the semiconductor chip without voids being formed, development of a resin composition having superior fluidity and filling ability has been desired.

### RELATED DOCUMENT

### Patent Document

[Patent Document 1] Japanese Unexamined Patent Publication NO. 2004-307645

### DISCLOSURE OF THE INVENTION

### Problems to be Solved by the Invention

The present invention relates to provision of a resin composition capable of exhibiting superior fluidity and filling ability; and a highly reliable semiconductor device using this resin composition.

### Means for Solving the Problem

According to the present invention, there is provided a resin composition for encapsulation including: a curing resin (B); and an inorganic filler (C), in which the resin composition encapsulates a semiconductor element provided over a substrate and fills a gap between the substrate and the semiconductor element, and when a particle diameter at a cumulative frequency of 5% in order from the largest particle diameter in a volume particle diameter distribution of particles contained in the inorganic filler (C) is represented by Rₘₐₓ (μm), and when a maximum peak diameter in the volume particle diameter distribution of the particles contained in the inorganic filler (C) is represented by R (μm), R<Rₘₐₓ, 1 μm≦R≦24 μm, and R/Rₘₐₓ≧0.45.

In addition, according to the present invention, there is provided a resin composition including: a curing resin (B); and an inorganic filler, in which the resin composition encapsulates a semiconductor element provided over a substrate and fills a gap between the substrate and the semiconductor element during the encapsulation, the resin composition is obtained by mixing first particles (C1) contained in the inorganic filler and the curing resin (B), the first particles (C1) have a maximum particle diameter of R1ₘₐₓ (μm), and when a mode diameter of the first particles (C1) is represented by R1_{mode} (μm) a relationship of 4.5 μm≦R1_{mode}≦24 μm and a relationship of R1_{mode}/R1ₘₐₓ≧0.45 are satisfied.

Further, according to the present invention, there is provided a semiconductor device including: a substrate; a semiconductor element that is provided over the substrate; and a cured product of one of the above-described resin compositions that encapsulates the semiconductor element and fills a gap between the substrate and the semiconductor element.

### Effects of the Invention

According to the present invention, when sealing a semiconductor element, a resin composition having superior fluidity and curability can be provided. As a result, when the semiconductor element is encapsulated with the resin composition, the formability of the resin composition can be improved. In addition, the resin composition can reliably fill a gap between the semiconductor element and a substrate, and thus generation of voids can be suppressed. Therefore, the reliability of a product (semiconductor device according to the present invention) can be improved.

### BRIEF DESCRIPTION OF THE DRAWINGS

The above-described objects and other objects, features, and advantageous effects will be further clarified.

FIG. 1 is a graph illustrating a particle diameter distribution of first particles.

FIG. 2 is a graph illustrating a median diameter.

FIG. 3 is a cross-sectional view of a semiconductor package.

FIG. 4 is a side view schematically illustrating an example of a pulverizing device.

FIG. 5 is a plan view schematically illustrating the inside of a pulverizing portion of the pulverizing device of FIG. 4.

FIG. 6 is a cross-sectional view illustrating a chamber of the pulverizing portion of the pulverizing device of FIG. 4.

FIGS. 7 (a) and 7 (b) are diagrams illustrating a volume particle diameter distribution of particles contained in the resin composition.

### DESCRIPTION OF EMBODIMENTS

Hereinafter, preferred embodiments of a resin composition and a semiconductor device according to the present invention will be described.

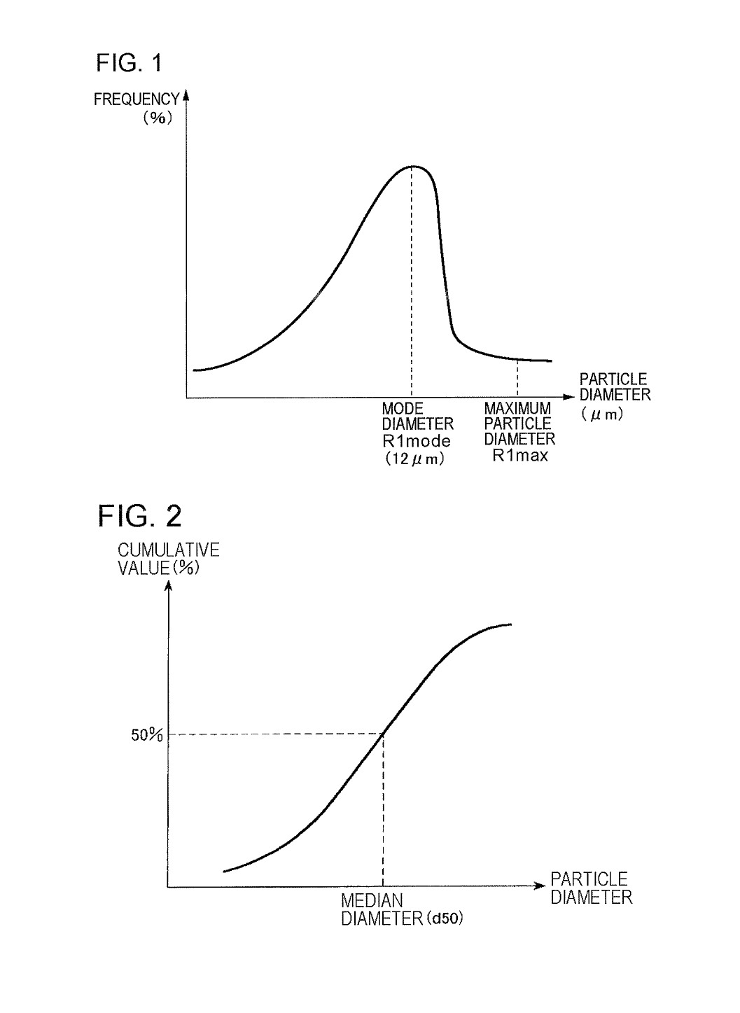

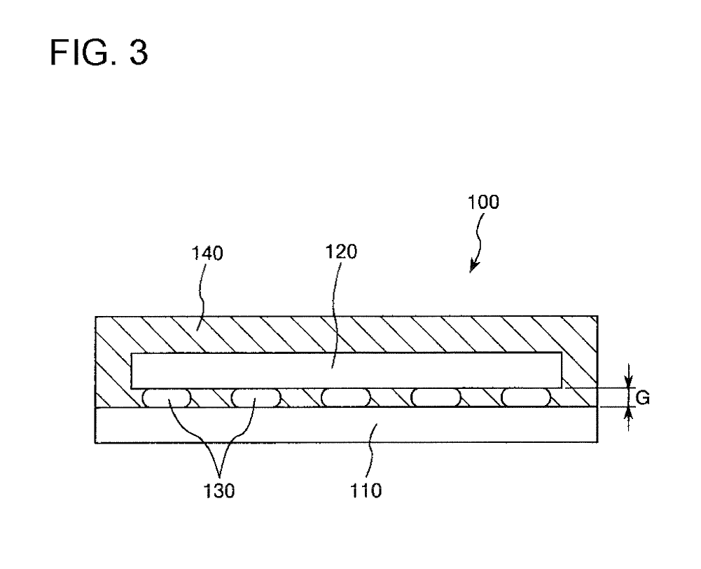

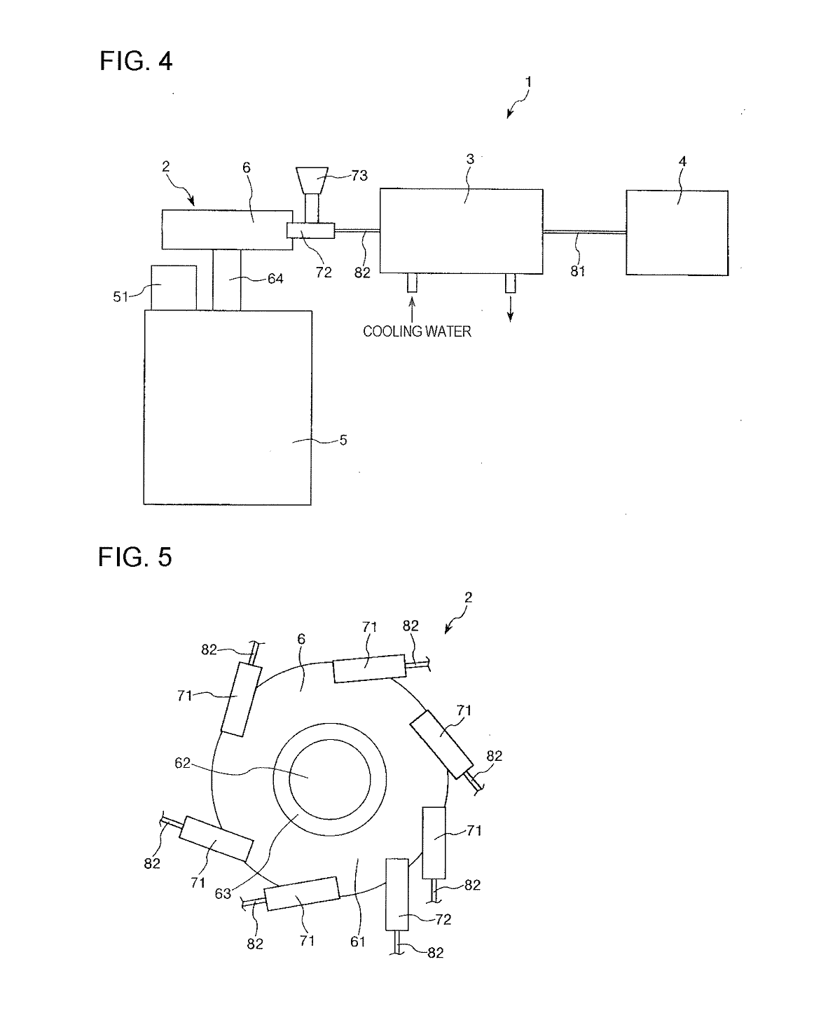

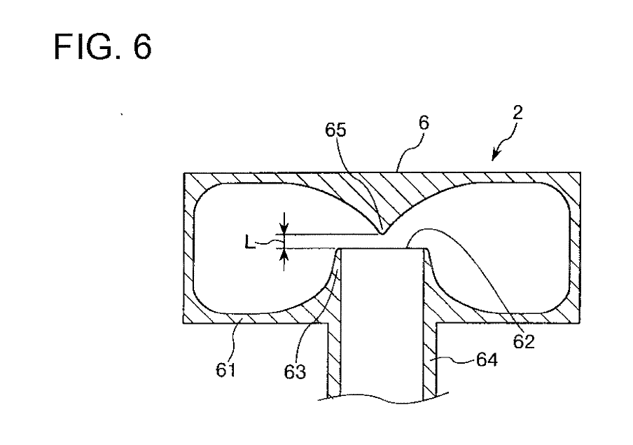

FIG. 1 is a graph illustrating a particle diameter distribution of first particles, FIG. 2 is a graph illustrating a median diameter, FIG. 3 is a cross-sectional view of a semiconductor package, FIG. 4 is a side view schematically illustrating an example of a pulverizing device, FIG. 5 is a plan view schematically illustrating the inside of a pulverizing portion of the pulverizing device of FIG. 4, and FIG. 6 is a cross-sectional view illustrating a chamber of the pulverizing portion of the pulverizing device of FIG. 4.

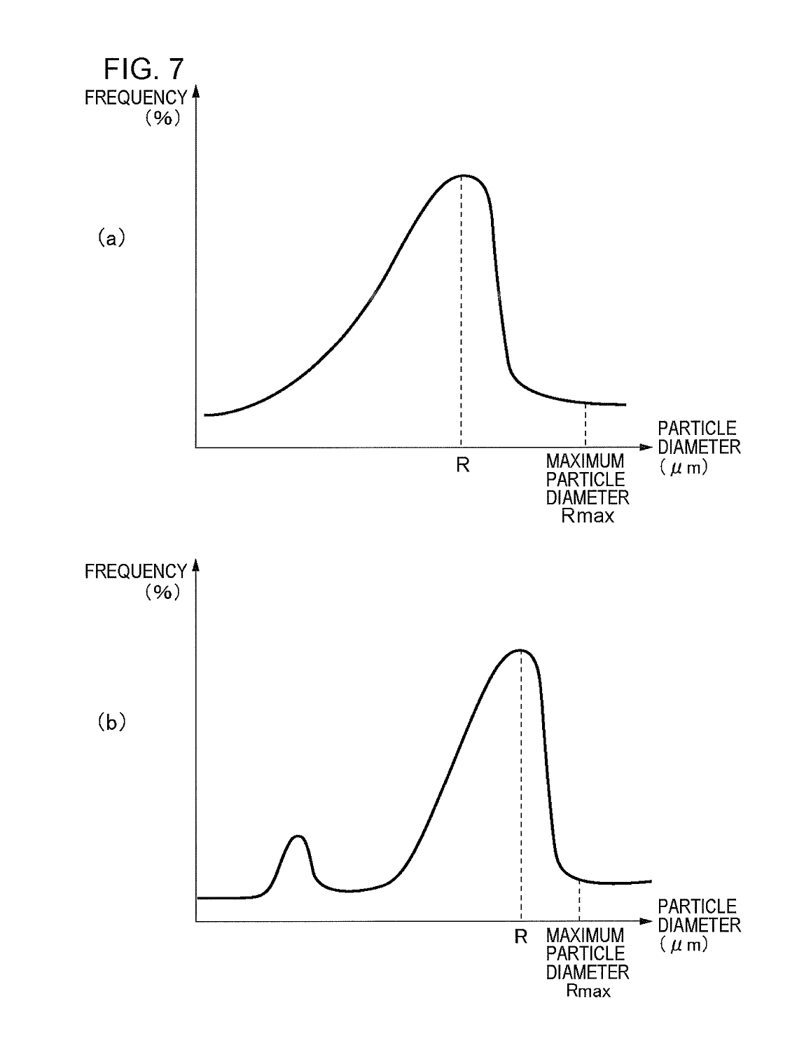

FIGS. 7 (a) and 7 (b) are diagrams illustrating a volume particle diameter distribution of all the particles contained in the resin composition.

1. Resin Composition

The resin composition (A) includes a curing resin (B), an inorganic filler (C) and optionally further includes a curing accelerator (D) and a coupling agent (E). Examples of the curing resin include epoxy resins, and it is preferable that an epoxy resin in which a phenolic resin-based curing agent is used as the curing accelerator be used.

[Curing Resin (B)]

Examples of the curing resin (B) include thermosetting resins such as epoxy resins, and it is preferable that an epoxy resin (B1) and a phenolic resin-based curing agent (B2) as the curing agent be used in combination. A ratio of the curing resin to the total mass of the resin composition is, for example, 3 mass % to 45 mass %. The ratio of the curing resin to the total mass of the resin composition is preferably more than or equal to 5 mass % and less than or equal to 20 mass %.

Examples of the epoxy resin (B1) include crystalline epoxy resins such as bisphenol-type epoxy resins including biphenyl-type epoxy resins, bisphenol A-type epoxy resins, bisphenol F-type epoxy resins, and tetramethyl bisphenol F-type epoxy resins, and stilbene-type epoxy resins; novolac type epoxy resins such as phenol-novolac type epoxy resins and cresol-novolac type epoxy resins; polyfunctional epoxy resins such as triphenol methane type epoxy resins and alkyl-modified triphenol methane type epoxy resins; phenol aralkyl type epoxy resins such as phenol aralkyl type epoxy resins having a phenylene skeleton, phenol aralkyl type epoxy resins having a biphenylene skeleton, naphthol aralkyl type epoxy resins having a phenylene skeleton, and naphthol aralkyl type epoxy resins having a biphenylene skeleton; naphthol type epoxy resins such as epoxy resins having a dihydroanthraquinone structure, dihydroxynaphthalene type epoxy resins, and epoxy resins obtainable by glycidyl etherifying dimers of dihydroxynaphthalene; triazine nucleus-containing epoxy resins such as triglycidyl isocyanurate and monoallyl diglycidyl isocyanurate; and bridged cyclic hydrocarbon compound-modified phenol type epoxy resins such as dicyclopentadiene-modified phenol type epoxy resins. Among these, one or more kinds can be used. However, the epoxy resin is not limited to these examples. From the viewpoint of the moisture resistance reliability of the obtained resin composition, it is preferable that these epoxy resins contain as less Na⁺ ions and Cl⁻ ions as possible which are ionic impurities. In addition, from the viewpoint of the curability of the resin composition, an epoxy equivalent of the epoxy resin (B) is preferably more than or equal to 100 g/eq and less than or equal to 500 g/eq.

The lower limit of a mixing ratio of the epoxy resin (B1) in the resin composition according to the present invention is preferably more than or equal to 3 mass %, more preferably more than or equal to 5 mass %, and still more preferably more than or equal to 7 mass % with respect to the total mass of the resin composition (A). When the lower limit is in the above-described range, the obtained resin composition has superior fluidity. In addition, the upper limit of the epoxy resin (B1) in the resin composition is preferably less than or equal to 30 mass % and more preferably less than or equal to 20 mass % with respect to the total mass of the resin composition. When the upper limit is in the above-described range, the obtained resin composition can obtain reliability such as superior solder resistance.

The phenolic resin-based curing agent (B2) includes all of monomers, oligomers, and polymers, each having two or more phenolic hydroxyl groups in one molecule, and a molecular weight and a molecular structure thereof are not particularly limited. Examples of the phenolic resin-based curing agent (B2) include novolac type resins such as phenol-novolac resins and cresol-novolac resins; modified phenolic resins such as terpene-modified phenolic resins and dicyclopentadiene-modified phenolic resins; phenol aralkyl resins having a phenylene skeleton or a biphenylene skeleton; bisphenol compounds such as bisphenol A and bisphenol F; and novolac compounds of the above-described bisphenol compounds. These examples may be used singly or in a combination of two or more kinds. From the viewpoint of curability, a hydroxyl equivalent of the phenolic resin-based curing agent is preferably more than or equal to 90 g/eq and less than or equal to 250 g/eq.

The lower limit of a mixing ratio of the phenolic resin-based curing agent (B2) in the resin composition (A) is not particularly limited, but is preferably more than or equal to 2 mass %, more preferably more than or equal to 3 mass %, and still more preferably more than or equal to 5 mass % with respect to the total mass of the resin composition (A). When the lower limit of the mixing ratio is in the above-described range, sufficient fluidity can be obtained. In addition, the upper limit of the mixing ratio of the phenolic resin-based curing agent (B2) in the resin composition (A) is not particularly limited, but is preferably less than or equal to 25 mass %, more preferably less than or equal to 15 mass %, and still more preferably less than or equal to 6 mass %. When the upper limit of the mixing ratio is in the above-described range, reliability such as superior solder resistance can be obtained.

It is preferable that the phenolic resin-based curing agent (B2) and the epoxy resin (B1) be mixed with each other such that an equivalent ratio (EP)/(OH) of the total number of epoxy groups (EP) in the epoxy resin (B1) to the total number of phenolic hydroxyl groups (OH) in the phenolic resin-based curing agent (B2) is more than or equal to 0.8 and less than or equal to 1.3. When the equivalent ratio is in the above-described range, sufficient curing characteristics can be obtained during the molding of the obtained resin composition (A).

[Curing Accelerator (D)]

When the epoxy resin (B1) is used as the curing resin and the phenolic resin-based curing agent (B2) is used as the curing agent, the curing accelerator (D) is not particularly limited as long as it accelerates a reaction between the epoxy groups of the epoxy resin (B1) and the phenolic hydroxyl groups of the compound containing two or more phenolic hydroxyl groups, and materials used for general epoxy resin compositions for semiconductor encapsulation can be used.

Specific examples of the curing accelerator (D) include phosphorus atom-containing curing accelerator such as organic phosphines, tetra-substituted phosphonium compounds, phosphobetaine compounds, adducts between phosphine compounds and quinone compounds, and adducts between phosphonium compounds and silane compounds; nitrogen atom-containing curing accelerators such as tertiary amines (for example, benzyldimethylamine), amidines (for example, 1,8-diazabicyclo(5,4,0)undecene-7 and 2-methylimidazole), and quaternary salts of the above-described tertiary amines and amidines. Among these, one or more kinds can be used. The phosphorus atom-containing curing accelerator can obtain preferable curability.

In addition, from the viewpoint of a balance between fluidity and curability, at least one compound selected from the group consisting of tetra-substituted phosphonium compounds, phosphobetaine compounds, adducts between phosphine compounds and quinone compounds, and adducts between phosphonium compounds and silane compounds is more preferable. When fluidity is emphasized, the tetra-substituted phosphonium compounds are particularly preferable. In addition, when low elastic modulus during the heating of a cured product of the resin composition is emphasized, the phosphobetaine compounds and the adducts between phosphine compounds and quinone compounds are particularly preferable. In addition, when potential curability is emphasized, adducts between phosphonium compounds and silane compounds are particularly preferable.

Examples of the organic phosphines which can be used in the resin composition (A) include primary phosphines such as ethylphosphine and phenylphosphine; secondary phosphines such as dimethylphosphine and diphenylphosphine; and tertiary phosphines such as trimethylphosphine, triethylphosphine, tributylphosphine, and triphenylphosphine. Among these, one or more examples can be used.

Examples of the tetra-substituted phosphonium compounds which can be used in the resin composition (A) include compounds represented by the following formula (1).

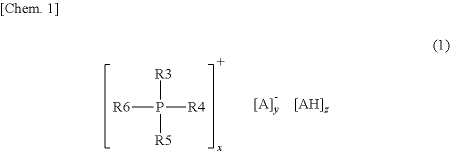

In the formula (1), P represents a phosphorus atom; R3, R4, R5, and R6 each independently represent an aromatic group or an alkyl group; A represents an anion of an aromatic organic acid containing at least one of functional groups selected from the group consisting of a hydroxyl group, a carboxyl group, and a thiol group in the aromatic ring; AH represents an aromatic organic acid containing at least one of functional groups selected from the group consisting of a hydroxyl group, a carboxyl group, and a thiol group in the aromatic ring; x and y each independently represent an integer of 1 to 3; z represents an integer of 0 to 3; and x=y.

The compound represented by the formula (1) is obtained, for example, as follows, but the present invention is not limited thereto. First, a tetra-substituted phosphonium halide, an aromatic organic acid, and a base are mixed and uniformly dissolved in an organic solvent to form anions of the aromatic organic acid in the solution system. Next, water is added to the solution system to precipitate the compound represented by the formula (1). In the compound represented by the formula (1), it is preferable that R3, R4, R5, and R6 bonded to the phosphorus atom each independently represent a phenyl group, AH represent a compound containing a hydroxyl group in an aromatic ring, that is, a phenol, and A represent an anion of the phenol. Examples of the phenol usable in the present invention include monocyclic phenols such as phenol, cresol, resorcin, and catechol; condensed polycyclic phenols such as naphthol, dihydroxynaphthalene, and anthraquinol; bisphenols such as bisphenol A, bisphenol F, and bisphenol S; and polycyclic phenols such as phenylphenol and biphenol. Among these, one or more kinds can be used.

Examples of the phosphobetaine compounds which can be used in the resin composition (A) include compounds represented by the following formula (2).

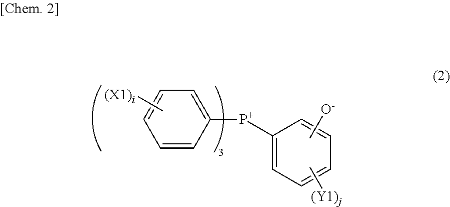

In the formula (2), X1 represents an alkyl group having 1 to 3 carbon atoms; Y1 represents a hydroxyl group; i represents an integer of 0 to 5; and j represents an integer of 0 to 4.

The compound represented by the formula (2) is obtained, for example, as follows. First, triaromatic-substituted phosphine which is a tertiary phosphine is brought into contact with a diazonium salt to substitute the triaromatic-substituted phosphine with a diazonium group of the diazonium salt. Through this process, the compound represented by the formula (2) is obtained. However, the present invention is not limited to this process.

Examples of the adducts between phosphine compounds and quinone compounds which can be used in the resin composition (A) include compounds represented by the following formula (3).

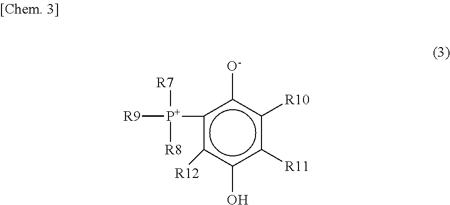

(In the formula (3), P represents a phosphorus atom; R7, R8, and R9 each independently represent an alkyl group having 1 to 12 carbon atoms or an aryl group having 6 to 12 carbon atoms and may be the same as or different from one another; and R10, R11, and R12 each independently represent a hydrogen atom or a hydrocarbon group having 1 to 12 carbon atoms, may be the same as or different from one another, and R10 and R11 may be bonded to form a cyclic structure.)

Examples of the phosphine compounds which can be used in the adducts between phosphine compounds and quinone compounds include triphenylphosphine, tris(alkylphenyl)phosphine, tris(alkoxyphenyl)phosphine, trinaphthylphosphine, and tris(benzyl)phosphine. It is preferable that these phosphine compounds be unsubstituted or substituted with a substituent such as an alkyl group or an alkoxy group in the aromatic ring. Examples of the substituent such as an alkyl group or an alkoxy group include those having 1 to 6 carbon atoms. Among these, one or more kinds can be used. From the viewpoint of availability, triphenylphosphine is preferable.

Examples of the quinone compounds which can be used in the adducts between phosphine compounds and quinone compounds include o-benzoquinone, p-benzoquinone, and anthraquinones. Among these, one or more kinds can be used. Among these, p-benzoquinone is preferable from the viewpoint of storage stability.

As a method of preparing the adducts between phosphine compounds and quinone compounds, an organic tertiary phosphine and a benzoquinone are dissolved in a solvent in which both compounds can be dissolved and are mixed to obtain an adduct. As the solvent, a solvent having low solubility to the adducts is preferable, for example, ketones such as acetone and methyl ethyl ketone. However, the solvent is not limited to these examples.

Among the compounds represented by the formula (3), a compound in which R7, R8, and R9 bonded to a phosphorus atom each independently represent a phenyl group and R10, R11, and R12 each independently represent a hydrogen group, that is, a compound by addition of 1,4-benzoquinone and triphenylphosphine is preferable from the viewpoints of maintaining elastic modules to be low during the heating of a cured product of the resin composition.

Examples of the adducts between phosphonium compounds and silane compounds which can be used in the resin composition according to the present invention include compounds represented by the following formula (4).

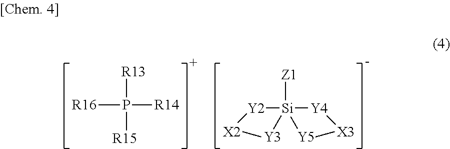

In the formula (4), P represents a phosphorus atom; Si represents a silicon atom; R13, R14, R15, and R16 each independently represent an organic group having an aromatic ring or a heterocyclic ring or an aliphatic group and may be the same as or different from one another; X2 represents an organic group bonded to Y2 and Y3; X3 represents an organic group bonded to Y4 and Y5; Y2 and Y3 each independently represent a proton donor group from which protons are released, and Y2 and Y3 in the same molecule are bonded to the silicon atom to form a chelate structure; Y4 and Y5 each independently represent a proton donor group from which protons are released, and Y4 and Y5 in the same molecule are bonded to the silicon atom to form a chelate structure; X2 and X3 may be the same as or different from each other; Y2, Y3, Y4, and Y5 may be the same as or different from one another; and Z1 represents an organic group having an aromatic ring or a heterocyclic ring or an aliphatic group.

Examples of R13, R14, R15, and R16 in the formula (4) include a phenyl group, a methylphenyl group, a methoxyphenyl group, a hydroxyphenyl group, a naphthyl group, a hydroxynaphthyl group, a benzyl group, a methyl group, an ethyl group, an n-butyl group, an n-octyl group, and a cyclohexyl group. Among these, an aromatic group which is unsubstituted or substituted with a substituent such as a phenyl group, a methylphenyl group, a methoxyphenyl group, a hydroxyphenyl group, or a hydroxynaphthyl group is preferable.

In addition, in the formula (4), X2 represents an organic group bonded to Y2 and Y3. Likewise, X3 represents an organic group bonded to Y4 and Y5. Y2 and Y3 each independently represent a proton donor group from which protons are released, and Y2 and Y3 in the same molecule are bonded to the silicon atom to form a chelate structure. Likewise, Y4 and Y5 each independently represent a proton donor group from which protons are released, and Y4 and Y5 in the same molecule are bonded to the silicon atom to form a chelate structure. X2 and X3 may be the same as or different from each other, and Y2, Y3, Y4, and Y5 may be the same as or different from one another.

In the formula (4), groups represented by —Y2-X2-Y3- and —Y4-X3-Y5- include a group obtained by a proton donor releasing two protons. As the proton donor, for example, an organic acid having two or more carboxyl groups and/or hydroxyl groups is preferable, an aromatic compound having a carboxyl group or a hydroxyl group in each of two or more carbon atoms which form the aromatic ring is more preferable, and an aromatic compound having a hydroxyl group in at least two adjacent carbon atoms which form the aromatic ring is still more preferable.

Specific examples of the proton donor include catechol, pyrogallol, 1,2-dihydroxynaphthalene, 2,3-dihydroxynaphthalene, 2,2′-biphenol, 1,1′-bi-2-naphthol, salicylic acid, 1-hydroxy-2-naphthoic acid, 3-hydroxy-2-naphthoic acid, chloranilic acid, tannic acid, 2-hydroxybenzyl alcohol, 1,2-cyclohexanediol, 1,2-propanediol, and glycerin. Among these, catechol, 1,2-dihydroxynaphthalene, and 2,3-dihydroxynaphthalene are more preferable.

In addition, Z1 in the formula (4) represents an organic group having an aromatic ring or heterocyclic ring or an aliphatic group, and specific examples thereof include aliphatic hydrocarbon groups such as a methyl group, an ethyl group, a propyl group, a butyl group, a hexyl group, and an octyl group; aromatic hydrocarbon groups such as a phenyl group, a benzyl group, a naphthyl group, and a biphenyl group; and reactive substituents such as a glycidyloxypropyl group, a mercaptopropyl group, an aminopropyl group, and a vinyl group. Z1 can be selected from the above-described examples. Among these, a methyl group, an ethyl group, a phenyl group, a naphthyl group, and a biphenyl group are more preferable from the viewpoint of improving thermal stability of the formula (4).

As a method of preparing the adducts between phosphonium compounds and silane compounds, a silane compound such as phenyltrimethoxysilane and a proton donor such as 2,3-dihydroxynaphthalene are added to a flask containing methanol and are dissolved therein, and then a sodium methoxide-methanol solution is added dropwise under stirring at room temperature. Further, a methanol solution in which a tetra-substituted phosphonium halide such as tetraphenylphosphonium bromide is dissolved in methanol is prepared in advance and added dropwise under stirring at room temperature to precipitate crystals. The precipitated crystals are separated by filtration, is washed with water, and is dried under vacuum to obtain an adduct of the phosphonium compound and the silane compound. However, the present invention is not limited to this method.

A mixing ratio of the curing accelerator (D) which can be used in the resin composition (A) is preferably more than or equal to 0.1 mass % and less than or equal to 1 mass % with respect to the total mass of the resin composition (A). When the mixing amount of the curing accelerator (D) is in the above-described range, sufficient curability and fluidity can be obtained.

[Coupling Agent (E)]

Examples of the coupling agent (E) include silane compounds such as epoxysilane, aminosilane, ureidosilane, and mercaptosilane. The coupling agent (E) is not particularly limited as long as it is reacts with or works on the epoxy resin (B1) and the like and the inorganic filler (C) to improve an interfacial strength between the epoxy resin (B1) and the like and the inorganic filler (C).

Examples of the epoxysilane include γ-glycidoxypropyltriethoxysilane, γ-glycidoxypropyltrimethoxysilane, γ-glycidoxypropylmethyldimethoxysilane, and β-(3,4-epoxycyclohexyl)ethyltrimethoxysilane. Among these, one or more kinds can be used.

In addition, examples of the aminosilane include γ-aminopropyltriethoxysilane, γ-aminopropyltrimethoxysilane, N-β-(aminoethyl)-γ-aminopropyltrimethoxysilane, N-β-(aminoethyl)-γ-aminopropylmethyldimethoxysilane, N-phenyl-γ-aminopropyltriethoxysilane, N-phenyl-γ-aminopropyltrimethoxysilane, N-β-(aminoethyl)-γ-aminopropyltriethoxysilane, N-6-(aminohexyl)-3-aminopropyltrimethoxysilane, and N-(3-(trimethoxysilylpropyl)-1,3-benzenedimethanane. A latent aminosilane coupling agent protected by reacting a primary amino moiety of aminosilane with ketone or aldehyde may be used. In addition, examples of the ureidosilane include γ-ureidopropyltriethoxysilane and hexamethyldisilazane. In addition, examples of the mercaptosilane include a silane coupling agent exhibiting the same function as the mercaptosilane coupling agent by thermal decomposition, such as bis(3-triethoxysilylpropyl)tetrasulfide and bis(3-triethoxysilylpropyl)disulfide, in addition to γ-mercaptopropyltrimethoxysilane and 3-mercaptopropylmethyldimethoxysilane. In addition, these silane coupling agents may also be added after hydrolyzing in advance. These silane coupling agents may be used singly or in a combination of two or more kinds.

The lower limit of a mixing ratio of the coupling agent (E) which can be used in the resin composition (A) is preferably more than or equal to 0.01 mass %, more preferably more than or equal to 0.05 mass %, and particularly preferably more than or equal to 0.1 mass % with respect to the total mass of the resin composition (A). When the lower limit of the mixing ratio of the coupling agent (E) is in the above-described range, an interfacial strength between the epoxy resin and the inorganic filler is not decreased, and superior solder cracking resistance in a semiconductor device can be obtained. In addition, the upper limit of the mixing ratio of the coupling agent is preferably less than or equal to 1.0 mass %, more preferably less than or equal to 0.8 mass %, and particularly preferably less than or equal to 0.6 mass % with respect to the total mass of the resin composition. When the upper limit of the mixing ratio of the coupling agent is in the above-described range, an interfacial strength between the epoxy resin (B1) and the inorganic filler (C) is not decreased, and superior solder cracking resistance in a semiconductor device can be obtained. In addition, when the mixing ratio of the coupling agent (E) is in the above-described range, the water absorbency of a cured product of the resin composition (A) is not increased, and superior solder cracking resistance in a semiconductor device can be obtained.

[Inorganic Filler (C)]

By the resin composition containing the inorganic filler (C), a difference in thermal expansion coefficient between the resin composition and the semiconductor element can be decreased, and a more highly reliable semiconductor device (semiconductor device according to the present invention) can be obtained.

Hereinafter, in order to measure and evaluate a particle diameter distribution such as a mode diameter or a median diameter, a laser diffraction scattering particle diameter distribution analyzer SALD-7000 manufactured by Shimadzu Corporation is used.

A constituent material of the inorganic filler (C) is not particularly limited, and examples thereof include fused silica, crystalline silica, alumina, silicon nitride, and aluminum nitride. Among these, one or more kinds can be used. Among these, fused silica is preferably used as the inorganic filler (C) from the viewpoint of superior versatility. In addition, the inorganic filler (C) is preferably spherical, and spherical silica is more preferable. As a result, the fluidity of the resin composition is improved.

As the inorganic filler (C), first particles (C1) can be used. The resin composition (A) containing the first particles (C1) and the above-described curing resin can be obtained. Although described below, the inorganic filler (C) may further include third particles (C3) in addition to the first particles (C1).

Here, the first particles (C1) contained in the inorganic filler (C) will be described. It is preferable that the first particles (C1) ((C1) is a component of (C)) of the inorganic filler (C) be selected to satisfy a relationship of R<Rₘₐₓ and relationships of 1 μm≦R≦24 μm and R/Rₘₐₓ≧0.45 (R and Rₘₐₓ will be described below). For example, a maximum particle diameter R1ₘₐₓ of the first particles (C1) is more than a mode diameter R1_{mode} described below of the first particles (C1) and is preferably more than or equal to 3 μm and less than or equal to 48 μm and more preferably more than or equal to 4.5 μm and less than or equal to 32 μm. When the mode diameter is less than or equal to 20 μm, the maximum particle diameter R1ₘₐₓ, is more than the mode diameter R1_{mode} and is 3 μm to 24 μm and preferably 4.5 μm to 24 μm.

When the mode diameter is less than or equal to 20 μm, the maximum particle diameter R1ₘₐₓ of the first particles (C1) is preferably 24 μm.

However, when the particles contained in the inorganic filler (C) are the first particles (C1), Rₘₐₓ of the inorganic filler (C) matches with the maximum particle diameter of the first particles (C1), and R of the inorganic filler (C) matches with the mode diameter R1_{mode} of the first particles (C1).

By satisfying the above-described range, the resin composition (A) can reliably fill a fine gap (for example, a gap having a size of about 30 μm or less between a circuit substrate 110 and a semiconductor chip 120 described below). When the maximum particle diameter of the first particles (C1) is less than the lower limit, the fluidity of the resin composition (A) may deteriorate depending on the content of the inorganic filler (C) in the resin composition (A) and the like.

The maximum particle diameter of the first particles (C1) refers to d₉₅, that is, a particle diameter at a cumulative frequency of 5% in order from the largest particle diameter in a volume particle diameter distribution of the first particles (C1). In addition, when the first particles (C1) are sieved, a meshON (amount of a residue after sieving) in a sieve having a pore size corresponding to the maximum particle diameter is less than or equal to 1%.

In the resin composition (A), when the mode diameter of the first particles (C1) is represented by R1_{mode} it is preferable that a relationship of 1 μm≦R1_{mode}≦24 μm be satisfied, and it is particularly preferable that a relationship of 4.5 μm≦R1_{mode}≦24 μm be satisfied.

In addition, in the resin composition (A), when the maximum particle diameter of the first particles (C1) is represented by R1ₘₐₓ, a relationship of R1_{mode}/R1ₘₐₓ≧0.45 is satisfied. By satisfying these two relationships, the resin composition (A) exhibits superior fluidity and filling ability.

“The mode diameter” refers to a particle diameter having a highest frequency (by volume) in the first particles (C1). Specifically, FIG. 1 illustrates an example of a particle diameter distribution of the first particles (C1), and in the first particles (C1) having the particle diameter distribution of FIG. 1, 12 μm which is a particle diameter having a highest frequency (%) corresponds to the mode diameter R1_{mode}.

As illustrated in FIG. 1, a high proportion of particles in the first particles (C1) are particles having a particle diameter close to the mode diameter. Therefore, by controlling the mode diameter to be 1 (μm) to 24 (μm) and preferably 4.5 (μm) to 24 (μm), the particle diameter of a high proportion particles in the first particles (C1) can be controlled to be 1 (μm) to 24 (μm) and preferably 4.5 (μm) to 24 (μm). Accordingly, the upper limit of the particle diameter is set to be less than or equal to the size of a fine gap to fill the fine gap. Therefore, a problem of fluidity decrease in a filler of the related art in which particle diameters having a given particle diameter or more are removed can be solved by the invention, and the resin composition (A) having superior fluidity can be obtained.

The mode diameter R1_{mode} of the first particles (C1) only need to satisfy a relationship of 1 μm≦R1_{mode}≦24 μm and is preferably more than or equal to 3 μm and more preferably more than or equal to 4.5 μm. Further, R1_{mode} is more than or equal to 5 μm and particularly preferably more than or equal to 8 μm. On the other hand, R1_{mode} is preferably less than or equal to 20 μm. In addition, R1_{mode} may be less than or equal to 17 μm. More specifically, it is preferable that a relationship of 4.5 μm≦R1_{mode}≦24 μm be satisfied. In addition, it is more preferable that a relationship of 5 μm≦R1_{mode}≦20 μm be satisfied. Further, a relationship of 8 μm≦R1_{mode}≦17 μm may be satisfied. As a result, the above-described effects are more significantly exhibited.

When the maximum particle diameter of the first particles is 24 μm, R1_{mode} is preferably less than or equal to 14 μm, more preferably less than or equal to 17 μm, and still more preferably less than or equal to 20 μm.

The frequency of the first particles (C1) having a particle diameter corresponding to the mode diameter R1_{mode} is not particularly limited, but by volume, is preferably more than or equal to 3.5% and less than or equal to 15%, more preferably more than or equal to 4% and less than or equal to 10%, and still more preferably more than or equal to 4.5% and less than or equal to 9% with respect to the total volume of the inorganic filler (C). Further, the frequency is more than or equal to 5% and more preferably more than or equal to 6%. As a result, the first particles (C1) can be occupied by a high proportion of particles having the mode diameter R1_{mode} or a particle diameter close to the mode diameter R1_{mode}. Therefore, properties (filling ability and fluidity) derived from the mode diameter R1_{mode} can be reliably imparted to the resin composition (A). That is, the resin composition (A) having desired characteristics can be obtained. In addition, the productivity and the yield of the resin composition (A) are improved.

Although the particle diameter is defined as “average particle diameter” in most inventions of the related art, “average particle diameter” described herein generally refers to a median diameter (d₅₀). This median diameter (d₅₀) refers to, when particle diameters of powder (E) including many particles are divided into a larger side and a smaller side centering on a particle diameter as illustrated in FIG. 2, a particle diameter at which the mass or the volume of particles on the larger side is the same as particles on the smaller side. Therefore, for example, even in “particles having an average particle diameter of 16 μm”, the frequency of particles having a particle diameter close to 16 μm with respect to the entirety of the powder (E) is unclear. If the frequency of particles having a particle diameter close to 16 μm with respect to the entirety of the powder (E) is low, physical characteristics which are given to the resin composition by the particles having a particle diameter close to 16 μm are not predominant. Accordingly, physical characteristics which can be estimated from “average particle diameter” may not be imparted.

On the other hand, in the present invention, the particle diameter is defined using “the mode diameter” described above. Therefore, the above-described problems of the case where “the average particle diameter” is used do not occur, and the following physical characteristics which can be estimated from “the mode diameter” can be more reliably imparted to the resin composition (A). That is, in a flip-chip type semiconductor device in which a gap between a substrate and a semiconductor chip are extremely small, decrease in maximum particle diameter is necessary due to the limitation of the above-described gap, and decrease in the maximum particle diameter causes decrease in fluidity. That is, it is important to realize both decrease in the maximum particle diameter used in a flip-chip type semiconductor device in which the gap is extremely small and improvement of fluidity. In the present invention, in order to achieve this object, a relation of the maximum particle diameter not with the average particle diameter of the related art but with the mode diameter is focused on to increase a ratio of particles having a particle diameter which is less than or equal to the maximum particle diameter and close to the maximum particle diameter. In addition, the present invention is also characterized in that, during the molding of a flip-chip type semiconductor device in which a gap between a substrate and a semiconductor chip is extremely small, it can overcome a difficulty of filling the gap between the substrate and the semiconductor chip (that is, not simple fluidity but the problem of flow resistance at an interface between the resin composition and the substrate or the semiconductor chip), in which this difficulty is caused by the flow resistance at the interface between the resin composition and the substrate or the semiconductor chip.

The frequency of the first particles (C1) having a particle diameter of 0.8R1_{mode} to 1.2R1_{mode} with respect to the entirety of the inorganic filler (C) is not particularly limited and is preferably 10% to 60%, more preferably 12% to 50%, and still more preferably 15% to 45% by volume. By satisfying the above-described range, most of particles of the inorganic filler (C) can be occupied by the first particles (C1) having the mode diameter R1_{mode} or a particle diameter close to the mode diameter R1_{mode}. Therefore, physical characteristics (filling ability and fluidity) derived from the mode diameter R1_{mode} can be more reliably imparted to the resin composition (A). That is, the resin composition (A) having the desired physical characteristics (filling ability and fluidity) can be obtained.

In addition, by satisfying the above-described range, the first particles (C1) having a relatively smaller particle diameter than the mode diameter R1_{mode} can be made appropriately present in the inorganic filler (C). Therefore, the first particles (C1) having such a small particle diameter can be interposed between the first particles (C1) having a particle diameter close to the mode diameter R1_{mode}. That is, the inorganic filler (C) can be dispersed to be close-packed in the resin composition (A). As a result, the fluidity and the filling ability of the resin composition (A) are improved.

The frequency of the first particles (C1) having a relatively smaller particle diameter than the mode diameter R1_{mode}, specifically, the first particles (C1) having a particle diameter of 0.5R1_{mode} or less with respect to the entirety of the inorganic filler (C) is not particularly limited but is preferably about 5% to 10% by volume. As a result, the decrease in the fluidity of the resin composition (A) is suppressed, and the filling ability of the resin composition (A) can be improved.

As described above, the first particles (C1) only need to satisfy a relationship of R1_{mode}/R1ₘₐₓ≧0.45 but more preferably satisfies R1_{mode}/R1ₘₐₓ≧0.55. The above-described expression implies that, the closer to 1 R1_{mode}/R1ₘₐₓ is, the closer to the maximum particle diameter R1ₘₐₓ the mode diameter R1_{mode} is. Therefore, by R1_{mode}/R1ₘₐₓ satisfying the above-described relationships, most of the first particles (C1) can be occupied by particles having a particle diameter relatively close to the maximum particle diameter R1ₘₐₓ. Therefore, the fluidity of the resin composition can be improved.

The upper limit of R1_{mode}/R1ₘₐₓ is not particularly limited, but it is preferable that a relationship of R1_{mode}/R1ₘₐₓ≦0.9 be satisfied, and it is more preferable that a relationship of R1_{mode}/R1ₘₐₓ≦0.8 be satisfied. When R1_{mode}/R1ₘₐₓ is excessively close to 1, the frequency of the first particles (C1) having a particle diameter more than the mode diameter R1_{mode} is decreased. Accordingly, the frequency of the first particles (C1) having the mode diameter R1_{mode} or a particle diameter close to the mode diameter R1_{mode} may be decreased.

As the first particles (C1), particles which are classified using various classification methods can be used, but it is preferable that particles which are classified with a classification method using a sieve be used as the first particles (C1).

Hereinabove, the inorganic filler (C) has been described. A part or all the first particles (C1) may be subjected to a surface treatment of attaching a coupling agent on surfaces thereof. By performing such a surface treatment, the curing resin (B) and the first particles (C1) are likely to be adapted to each other, and the dispersibility of a filler such as the first particles (C1) in the resin composition (A) is improved. As a result, the above-described effects can be exhibited, and the productivity of the resin composition is improved as described below.

The content of the inorganic filler (C) is preferably 50 mass % to 93 mass %, more preferably 60 mass % to 93 mass %, and still more preferably 60 mass % to 90 mass % with respect to the total mass of the resin composition (A). As a result, the resin composition (A) having superior fluidity and filling ability and low thermal expansion coefficient can be obtained. When the content of the inorganic filler (C) is less than the above-described lower limit, the amount of resin components (the curing resin (B) and the curing agent (D)) in the resin composition (A) is increased, and the resin composition (A) is likely to absorb moisture. As a result, moisture absorption reliability is poor, and solder reflow cracking resistance and the like may be decreased. Conversely, when the content of the inorganic filler (C) is more than the above-described upper limit, the fluidity of the resin composition (A) may be decreased.

In addition, the inorganic filler (C) may optionally further contain third particles (C3). The third particles (C3) may be formed of the same material as the first particles (C1) or may be formed of a different material from the first particles (C1). The first particles and the third particles are prepared to obtain the inorganic filler (C).

Here, the third particles (C3) have a particle diameter distribution different from the first particles (C1), and the mode diameter of the third particles is less than the mode diameter of the first particles.

When the inorganic filler (C) contains the third particles (C3), the average particle diameter (median diameter (d₅₀)) of the third particles (C3) is preferably more than or equal to 0.1 μm and less than or equal to 3 μm and more preferably more than or equal to 0.1 μm and less than or equal to 2 μm. In addition, the specific surface area of the third particles (C3) is preferably more than or equal to 3.0 m²/g and less than or equal to 10.0 m²/g and more preferably more than or equal to 3.5 m²/g and less than or equal to 8 m²/g.

The content of the third particles (C3) is preferably more than or equal to 5 mass % and less than or equal to 40 mass % with respect to the total mass of the inorganic filler (C). The content of the third particles (C3) is more preferably more than or equal to 5 mass % and less than or equal to 30 mass % with respect to the total mass of the inorganic filler (C).

In this case, the content of the first particles (C1) is preferably more than or equal to 60 mass % and less than or equal to 95 mass % and particularly preferably more than or equal to 70 mass % and less than or equal to 95 mass % with respect to the total mass of the inorganic filler (C).

By the inorganic filler (C) containing the third particles, the fluidity of the resin composition can be further improved.

Next, the entirety of the inorganic filler (C) will be described.

The inorganic filler (C) is formed of powder containing particles and is preferably formed of only particles.

When a particle diameter at a cumulative frequency of 5% in order from the largest particle diameter in a volume particle diameter distribution of all the particles (all the particles contained in the resin composition) contained in the inorganic filler (C) is represented by Rₘₐₓ (μm), and when a maximum peak diameter in the volume particle diameter distribution of all the particles contained in the inorganic filler is represented by R (μm), R<Rₘₐₓ, 1 μm≦R≦24 μm, and R/Rₘₐₓ≦0.45.

The inorganic filler (C) may contain only the above-described first particles or may further contain the third particles in addition to the first particles. The above-described first particles and optionally the third particles may be selected so as to satisfy the above-described conditions.

Here, Rₘₐₓ (μm) refers to so-called d₉₅, that is, a particle diameter at a cumulative frequency of 95 mass % in order from the smallest particle diameter in the volume particle diameter distribution.

In addition, when the particles contained in the inorganic filler (C) are sieved, a meshON (amount of a residue after sieving) in a sieve having a pore size corresponding to the maximum particle diameter Rₘₐₓ is less than or equal to 1%.

As illustrated in FIGS. 7(a) and 7(b), R (μm) refers to a particle diameter at a maximum peak of the volume particle diameter distribution of the particles contained in the inorganic filler. In the embodiment, R refers to a first peak diameter in order from the largest particle diameter in the volume particle diameter distribution of all the particles contained in the inorganic filler.

FIG. 7 (a) illustrates an example of a volume particle diameter distribution of all the particles when the inorganic filler contains only the first particles, and FIG. 7(b) illustrates an example of a volume particle diameter distribution of all the particles when the inorganic filler contains the first particles and the third particles.

By controlling R to be less than or equal to 24 μm, the resin composition (A) can reliably fill a fine gap (for example, a gap having a size of about 30 μm or less between the circuit substrate 110 and the semiconductor chip 120 described below). In addition, by controlling R to be more than or equal to 1 μm, the fluidity of the resin composition (A) can be improved.

The particles contained in the inorganic filler satisfy relationships of 1 μm≦R≦24 μm and R/Rₘₐₓ≧0.45.

By satisfying these two relationships, the resin composition (A) has superior fluidity and filling ability.

When Rₘₐₓ satisfies a relationship 1 μm≦R≦24 μm, Rₘₐₓ is more than R, and R/Rₘₐₓ≧0.45 may be satisfied. Rₘₐₓ is preferably more than or equal to 3 μm and less than or equal to 48 μm and more preferably more than or equal to 4.5 μm and less than or equal to 32 μm. When R is less than or equal to 20 μm, Rₘₐₓ is more than R and is preferably 3 μm to 24 μm and more preferably 4.5 μm to 24 μm.

By satisfying the above-described range, the resin composition (A) can reliably fill a fine gap (for example, a gap having a size of about 30 μm or less between the circuit substrate 110 and the semiconductor chip 120 described below).

By controlling R to be 1 (μm) to 24 (μm), the particle diameter of a high proportion of particles can be controlled to be about 1 (μm) to 24 (μm). Accordingly, the upper limit of the particle diameter is set to be less than or equal to the size of a fine gap to fill the fine gap. Therefore, a problem of fluidity decrease in a filler of the related art in which particle diameters having a given particle diameter or more are removed can be solved by the invention, and the resin composition (A) having superior fluidity can be obtained.

R only need to satisfy a relationship of 1 μm≦R≦24 μm and is preferably more than or equal to 3 μm and more preferably more than or equal to 4.5 μm. Further, R is more than or equal to 5 μm and particularly preferably more than or equal to 8 μm. On the other hand, R is preferably less than or equal to 20 μm. In addition, R may be less than or equal to 17 μm. More specifically, it is preferable that a relationship of 4.5 μm≦R≦24 μm be satisfied. In addition, it is more preferable that a relationship of 5 μm≦R≦20 μm be satisfied. Further, a relationship of 8 μm≦R≦17 μm may be satisfied. As a result, the above-described effects are more significantly exhibited.

When Rₘₐₓ of the particles is 24 μm, R is preferably less than or equal to 14 μm, more preferably less than or equal to 17 μm, and still more preferably less than or equal to 20 μm.

The frequency of particles having the particle diameter of R (μm) in the volume particle diameter distribution of all the particles contained in the inorganic filler is preferably more than or equal to 3.5% and less than or equal to 15%, more preferably more than or equal to 4% and less than or equal to 10%, and still more preferably more than or equal to 4.5% and less than or equal to 9%. Further, the frequency is more than or equal to 5% and more preferably more than or equal to 6%. As a result, the proportion of particles having the particle diameter of R or a particle diameter close to R can be increased. Therefore, the resin composition (A) having high fluidity can be obtained.

In addition, R/Rₘₐₓ only needs to be more than or equal to 0.45 but is preferably more than or equal to 0.55. Most of the particles can be occupied by particles having a particle diameter relatively close to Rₘₐₓ. Therefore, the fluidity of the resin composition can be improved.

The upper limit of R/Rₘₐₓ is not particularly limited but is preferably less than or equal to 0.9 and particularly preferably less than or equal to 0.8. When R/Rₘₐₓ is excessively close to 1, the frequency of the particles having a particle diameter more than R is decreased. Accordingly, the frequency of the particles having the particle diameter of R or a particle diameter close to the mode diameter R may be decreased.

Further, when a particle diameter at a cumulative frequency of 50% in order from the smallest particle diameter in a volume particle diameter distribution of particles contained in the inorganic filler is represented by d₅₀ (μm), R is more than d₅₀, and R/d₅₀ is preferably 1.1 to 15, more preferably 1.1 to 10, and still more preferably 1.1 to 5. d₅₀ (μm) refers to a particle diameter at a cumulative frequency of 50 mass % in order from the smallest particles in the volume particle diameter distribution.

In the embodiment, R is approximated to Rₘₐₓ, and thus a difference between R and d₅₀ is increased. By controlling R/d₅₀ to be more than or equal to 1.1, the fluidity of the resin composition is improved.

In addition, controlling R/d₅₀ to be less than or equal to 15, an excessive increase in the difference between R and d₅₀ is suppressed, and a certain amount of particles having the particle diameter of R (μm) and a particle diameter close to R (μm) can be secured.

In addition, the frequency of the particles having a particle diameter of 0.8×R (μm) to 1.2×R (μm) with respect to the entirety of the inorganic filler (C) is not particularly limited and is preferably 10% to 60%, more preferably 12% to 50%, and still more preferably 15% to 45% by volume. By satisfying the above-described range, most of particles of the inorganic filler (C) can be occupied by the particles having the particle diameter of R (μm) or a particle diameter close to R (μm). Therefore, physical characteristics (filling ability and fluidity) derived from R (μm) can be more reliably imparted to the resin composition (A). That is, the resin composition having the desired physical characteristics (filling ability and fluidity) can be obtained.

In addition, the frequency of particles having a relatively smaller particle diameter than R, specifically, particles having a particle diameter of 0.5R or less with respect to the entirety of the inorganic filler (C) is not particularly limited but is preferably about 5% to 50% by volume. As a result, the decrease in the fluidity of the resin composition (A) is suppressed, and the filling ability of the resin composition (A) can be improved.

An inorganic filler is preferably formed of only the inorganic filler (C) according to the present application but may further contain an inorganic filler other than the inorganic filler (C) within a range not departing from the effects of the present application.

Hereinabove, the composition of the resin composition (A) has been described in detail. The gel time of the resin composition (A) is not particularly limited but is preferably 35 seconds to 80 seconds and more preferably 40 seconds to 50 seconds. By setting the gel time of the resin composition (A) to the above-described numerical value, the curing time can have a margin, and the resin composition (A) can fill the gap relatively slowly. Therefore, the occurrence of voids can be effectively prevented. In addition, a decrease in productivity caused by an increase in gel time can be suppressed.

Further, in the resin composition (A), a spiral flow length which is measured when a mold for measuring spiral flow according to ANSI/ASTM D 3123-72 is injected under conditions of a mold temperature of 175° C., an injection pressure of 6.9 MPa, and a holding time of 120 seconds is preferably more than or equal to 70 cm. The spiral flow length is more preferably more than or equal to 80 cm. The upper limit of the spiral flow length is not particularly limited but is, for example, 100 cm.

In addition, in the resin composition (A), a pressure A which is measured under the following conditions is preferably less than or equal to 6 MPa. The pressure A is more preferably less than or equal to 5 MPa. In addition, the pressure A is preferably more than or equal to 2 MPa.

(Conditions)

Under conditions of a mold temperature of 175° C. and an injection speed of 177 cm³/sec, the resin composition is injected into a rectangular flow channel formed of the mold and having a width of 13 mm, a height of 1 mm, and a length of 175 mm, a pressure change over time is measured using a pressure sensor buried in a position of the flow channel which is distant from an upstream end by 25 mm, and a minimum pressure during the flowing of the resin composition is set as the pressure A.

The resin composition (A) having the above-described spiral flow and characteristics of the pressure A can have high fluidity and encapsulate a semiconductor element and can reliably fill a narrow gap between a semiconductor element and a substrate.

In addition, when the gap between the substrate and the semiconductor element which is filled with the resin composition (A) is represented by G (μm), R/G is preferably more than or equal to 0.05 and less than or equal to 0.7. R/G is more preferably more than or equal to 0.1 and less than or equal to 0.65. R/G is still more preferably more than or equal to 0.14 and less than or equal to 0.6.

With such a configuration, the resin composition (A) can reliably fill a narrow gap between a substrate and a semiconductor element.

2. Method of Preparing Resin Composition

Next, an example of a method of preparing the resin composition (A) will be described. The method of preparing the resin composition (A) is not limited to a method described below.

[Classification]

As a method of preparing an inorganic filler having a predetermined volume particle diameter distribution such as the above-described one, the following method may be used. Raw material particles of particles contained in the inorganic filler are prepared. These raw material particles do not have the above-described volume particle diameter distribution. These raw material particles are classified using Cyclone (air classification) to obtain the inorganic filler having a predetermined volume particle diameter distribution such as the above-described one. It is particularly preferable that a sieve be used because the inorganic filler having the particle diameter distribution according to the present application is likely to be obtained.

[Pulverization (First Pulverization)]

For example, using a pulverizer illustrated in FIG. 4, raw materials containing a powder material of the curing resin (B) and a powder material of the inorganic filler (C) are pulverized (finely pulverized) so as to have a predetermined particle diameter distribution. In this pulverization process, mainly, raw materials other than the inorganic filler (C) are pulverized. By the raw materials containing the inorganic filler (C), attachment of the raw materials on a wall surface of the pulverizer can be suppressed. In addition, by collision between the inorganic filler (C), which has a heavy specific gravity and is not easily dissolved, and the other components, the raw materials can be finely pulverized easily and reliably.

As the pulverizer, for example, a continuous rotary ball mill, or an airflow type pulverizer (airflow type pulverizing machine) can be used, but an airflow type pulverizer is preferably used. In the embodiment, an air flow type pulverizer 1 described below is used.

A part or the entirety of the inorganic filler (C) may be subjected to a surface treatment. As this surface treatment, for example, a coupling agent or the like is attached on a surface of the inorganic filler (C). By attaching the coupling agent on the surface of the inorganic filler (C), the curing resin (B) and the inorganic filler (C) are likely to be adapted to each other, the mixing property between the curing resin (b) and the inorganic filler (C) is improved, and the inorganic filler (C) is easily dispersed in the resin composition (A).

This pulverization process and the pulverizer 1 will be described in detail below.

[Kneading]

Next, the pulverized raw materials are kneaded using a kneader. As this kneader, for example, a kneading extruder such as a uniaxial kneading extruder or a biaxial kneading extruder and a roll type kneader such as a mixing roll can be used, but a biaxial kneading extruder is preferably used. In the embodiment, a case where a uniaxial kneading extruder or a biaxial kneading extruder is used will be described.

[Degassing]

Next, optionally, using a degasser, the kneaded resin composition may be degassed.

[Sheet Forming]

Next, using a sheet forming machine, the degassed massive resin composition is formed into a sheet shape to prepare a sheet-like resin composition. As this sheet forming machine, for example, a seating roll can be used.

[Cooling]

Next, using a cooler, the sheet-like resin composition is cooled. As a result, the pulverization of the resin composition can be performed easily and reliably.

[Pulverization (Second Pulverization)]

Next, using a pulverizer, the sheet-like resin composition is pulverized so as to have a predetermined particle diameter distribution to prepare a powdered resin composition. As this pulverizer, for example, a hammer mill, a grindstone type mill, or a roll crusher can be used.

As a method of preparing the granular or powdered resin composition (A), a granulation method represented by a hot cut method can be used without performing the above-described sheet forming process, cooling process, and pulverization process, in which, for example, a die having a small diameter is provided at an outlet of a kneader, a molten resin composition discharged from the die is cut into a predetermined length using a cutter or the like to prepare the granular or powdered resin composition (A). In this case, after the granular or powdered resin composition using the granulation method such as a hot cut method, the resin composition is preferably degassed such that the temperature of the resin composition is not decreased that much.

[Tablet Making]

Next, when a table-like molded product is prepared, using a molded product preparing machine (tablet making machine), the powdered resin composition (hereinafter, unless specified otherwise, the powdered resin composition includes the granular resin composition) can be compression-molded to prepare a resin composition which is a molded product (compressed product).

In the method of preparing the resin composition, the tablet making process may not be provided, and the powdered resin composition may be a final product.

3. Semiconductor Package

As illustrated in FIG. 3, the above-described resin composition according to the present invention is used for, for example, encapsulating the semiconductor chip (IC chip) 120 in a semiconductor package (semiconductor device) 100. In order to encapsulate the semiconductor chip 120 with the resin composition, a method may be used, the method including: molding the resin composition by transfer molding or the like; and encapsulating the semiconductor chip 120 with the resin composition which is an encapsulant (encapsulating unit) 140.

That is, the semiconductor package 100 includes: a circuit substrate (substrate) 110 (in the drawing, the dimension thereof is illustrated as being the same as the encapsulant 140 but is appropriately adjustable); and a semiconductor chip 120 that is electrically connected onto the circuit substrate 110 through metal bumps (connecting units) 130, in which the semiconductor chip 120 is encapsulated with the encapsulant 140 formed of the resin composition. In addition, when the semiconductor chip 120 is encapsulated, the resin composition fills a gap G between the circuit substrate 110 and the semiconductor chip 120, and thus the semiconductor package 100 is reinforced by the encapsulant 140 formed of the resin composition.

Here, when the semiconductor chip 120 is encapsulated with the resin composition by transfer molding, it is preferable that a method called molded array packaging (MAP) in which plural semiconductor chips 120 are collectively encapsulated be used. In this case, the semiconductor chips 120 are arranged in a matrix shape to be encapsulated with the resin composition (A) and then are cut into pieces. When the plural semiconductor chips 120 are collectively encapsulated using the above method, it is necessary that the fluidity of the resin composition be higher than that of a case where the semiconductor chips 120 are encapsulated one by one. The semiconductor chips 120 may be encapsulated one by one.

The resin composition can be desirably used in the case of a flip-chip type semiconductor device in which the distance (gap length) G between the semiconductor chip 120 and the circuit substrate 110 is 15 μm to 100 μm and a bump gap is 30 μm to 300 μm. In addition, the resin composition can be more desirably used in the case of a flip-chip type semiconductor device in which G is 15 μm to 40 μm and a bump gap is 30 μm to 100 μm.

First, the pulverizer 1 will be described. The pulverizer 1 is merely exemplary, and the present invention is not limited thereto. For example, each dimension is merely exemplary, and a different dimension may be adopted.

The pulverizer 1 illustrated in FIG. 4 is used in the pulverization process during the preparation of the resin composition. As illustrated in FIGS. 4 to 6, the pulverizer 1 is an airflow type pulverizer in which raw materials containing plural types of powder materials are pulverized by airflow. This pulverizer 1 includes a pulverizing unit 2 that pulverizes the raw materials, a cooler 3, a high-pressure air generating device 4, and a storage unit 5 in which the pulverized raw materials are stored.

The pulverizing unit 2 includes a chamber 6 having a cylindrical (tubular) portion. In this chamber 6, the raw materials are pulverized. During the pulverization, a swirl flow of air (gas) is generated in the chamber 6.

The dimension of the chamber 6 is not particularly limited. However, an average inner diameter of the chamber 6 is preferably about 10 cm to 50 cm and more preferably about 15 cm to 30 cm. In a configuration illustrated in the drawing, the inner diameter of the chamber 6 is constant along the vertical direction, but the present invention is not limited thereto. The inner diameter may change along the vertical direction.

In a bottom portion 61 of the chamber 6, an outlet 62 through which the pulverized raw materials are discharged is formed. This outlet 62 is positioned at the center of the bottom portion 61. In addition, the shape of the outlet 62 is not particularly limited but is circular in the configuration illustrated in the drawing. In addition, the dimension of the outlet 62 is not particularly limited, but the diameter thereof is preferably about 3 cm to 30 cm and more preferably about 7 cm to 15 cm.

In addition, in the bottom portion 61 of the chamber 6, a pipe line (pipe) 64 is provided, in which one end thereof is connected to the outlet 62, and the other end thereof is connected to the storage unit 5.

In addition, in the vicinity of the outlet 62 of the bottom portion 61, a wall portion 63 that surrounds the outlet 62 is formed. Due to this wall portion 63, the raw materials can be prevented from being discharged from the outlet 62 during the pulverization.

The wall portion 63 is tubular. In the configuration illustrated in the drawing, the inner diameter of the wall portion 63 is constant along the vertical direction, and the outer diameter thereof gradually increases from the upside to the downside. That is, the height (length in the vertical direction) of the wall portion 63 gradually increases from the outer peripheral side to the inner peripheral side. In addition, the wall portion 63 is curved in a concave shape when seen from the side. As a result, the pulverized raw materials can be smoothly moved toward the outlet 62.

In addition, a protrusion portion 65 is formed at a position of an upper region of the chamber 6 corresponding to the outlet 62 (pipe line 64). In the configuration illustrated in the drawing, a tip end (lower end) of this protrusion portion 65 is positioned above an upper end (outlet 62) of the wall portion 63, but the present invention is not limited thereto. The tip end of the protrusion portion 65 may be positioned below the upper end of the wall portion 63. Alternatively, a position of the tip end of the protrusion portion 65 and a position of the upper end of the wall portion 63 in the vertical direction match with each other.

The dimensions of the wall portion 63 and the protrusion portion 65 are not particularly limited. A length L from the upper end (outlet 62) of the wall portion 63 to the tip end (lower end) of the protrusion portion 65 is preferably about −10 mm to 10 mm and more preferably about −5 mm to 1 mm.

The symbol “−” of the length L implies that the tip end of the protrusion portion 65 is positioned below the upper end of the wall portion 63, and the symbol “+” of the length L implies that the tip end of the protrusion portion 65 is positioned above the upper end of the wall portion 63.

In addition, on side portions (side surfaces) of the chamber 6, plural nozzles (first nozzles) 71 that discharge air (gas) blown from the high-pressure air generating device 4 described below into the chamber 6 are provided. Each of the nozzles 71 is provided along a circumferential direction of the chamber 6. An interval (angular interval) between two adjacent nozzles 71 may be the same as or different from one another but is preferably set to be the same as one another. In addition, each of the nozzles 71 is provided to be inclined in a direction of a radius (radius crossing a tip end of the nozzle 71) of the chamber 6 when seen from in a plan view. The number of the nozzles 71 is not particularly limited but is preferably about 5 to 8.

Major components of swirl flow generating means for generating a swirl flow of air (gas) in the chamber 6 are composed of the respective nozzles 71 and the high-pressure air generating device 4.

In addition, on the side portions of the chamber 6, a nozzle (second nozzle) 72 that discharges (introduces) the raw materials into the chamber 6 along with the air blown from the high-pressure air generating device 4 are provided. By the nozzle 72 being provided on the side portions of the chamber 6, the raw materials discharged from the nozzle 72 into the chamber 6 can start to swirl instantly along with the swirl flow of air.

A position of the nozzle 72 on the side portions of the chamber 6 is not particularly limited, but the nozzle 72 is arranged between two adjacent nozzles 71 in the configuration illustrated in the drawing. In addition, a position of the nozzle 72 in the vertical direction may be the same as or different from the nozzles 71 but is preferably the same as the nozzles 71. In addition, the nozzle 72 is provided to be inclined in a direction of a radius (radius crossing a tip end of the nozzle 72) of the chamber 6 when seen from in a plan view.

For example, all the nozzles including the respective nozzles 71 and the nozzle 72 can be configured to be arranged at regular intervals (regular angular intervals). In this case, an interval between two nozzles 71 positioned adjacent to the nozzle 72 is two times an interval between two adjacent nozzles 71. In addition, a configuration in which the respective nozzles 71 are provided at regular intervals (regular angular intervals) and the nozzle 72 is arranged at an intermediate position between two adjacent nozzles 71 can be adopted. From the viewpoint of pulverization efficiency, the configuration in which the respective nozzles 71 are provided at regular intervals (regular angular intervals) and the nozzle 72 is arranged at an intermediate position between two adjacent nozzles 71 is preferable.

In addition, a cylindrical supply unit (supply means) 73 that is connected to the inside of the nozzle 72 and supplies the raw materials is provided above the nozzle 72. An end portion (upper end portion) above the supply unit 73 is tapered such that the inner diameter thereof gradually increases from the lower side to the upper side. In addition, an opening (upper end opening) of the upper end of the supply unit 73 forms a supply port and is arranged at a position deviating from the center of the swirl flow of air in the chamber 6. The raw materials supplied from this supply unit 73 are supplied from the nozzle 72 into the chamber 6.

The storage unit 5 includes an air vent unit 51 that discharges air (gas) in the storage unit 5 to the outside. This air vent unit 51 is provided above the storage unit 5 in the configuration illustrated in the drawing. In addition, the air vent unit 51 is provided with a filter through which air (gas) passes and the raw materials do not pass. As this filter, for example, a filter cloth can be used.

The high-pressure air generating device 4 is connected to the cooler 3 through a pipe line 81, and the cooler 3 is connected to the respective nozzles 71 and the nozzle 72 of the pulverizing unit 2 through a pipe line 82 from which plural pipe lines are branched.

The high-pressure air generating device 4 is a device that compresses air (gas) to blow high-pressure air (compressed air) and is configured to adjust the flow rate or the pressure of the blowing air. In addition, the high-pressure air generating device 4 has a function of drying the blowing air to decrease the humidity thereof and is configured to adjust the humidity of the blowing air. Due to this high-pressure air generating device 4, the above-described air is dried before being discharged from the nozzles 71 and 72 (before being supplied into the chamber 6). Accordingly, the high-pressure air generating device 4 functions as pressure adjusting means and humidity adjusting means.

The cooler 3 is a device that cools the air blown from the high-pressure air generating device 4 before the air is discharged from the nozzles 71 and 72 (before the air is supplied into the chamber 6) and is configured to adjust the temperature of the air. Accordingly, the cooler 3 functions as temperature adjusting means. As this cooler 3, for example, a liquid refrigerant type device or a gaseous refrigerant type device can be used.

Hereinafter, reference configurations are appended.

<Appendix>

(1) A resin composition including:

a curing resin; and

an inorganic filler,

wherein the resin composition encapsulates a semiconductor element provided over a substrate and fills a gap between the substrate and the semiconductor element during the encapsulation, and

the inorganic filler contains first particles having a maximum particle diameter of R1ₘₐₓ (μm), and

when a mode diameter of the first particles is represented by R1_{mode} (μm), a relationship of 4.5≦R1_{mode}≦24 and a relationship of R1_{mode}/R1ₘₐₓ≧0.45 are satisfied.

(2) A resin composition including:

a curing resin; and

an inorganic filler,

in which the resin composition encapsulates a semiconductor element provided over a substrate and fills a gap between the substrate and the semiconductor element during the encapsulation, and

the inorganic filler contains first particles having a maximum particle diameter of R1ₘₐₓ (μm) and second particles having a particle diameter more than R1ₘₐₓ (μm),

the second particles occupy 1% or less (excluding 0%) of the total volume of the inorganic filler, and

when a mode diameter of the first particles is represented by R1_{mode} (μm), a relationship of 4.5≦R1_{mode}≦24 and a relationship of R1_{mode}/R1ₘₐₓ≧0.45 are satisfied.

(3) The resin composition according to (1) or (2),

in which R1ₘₐₓ (μm) is 24 (μm).

(4) The resin composition according to any one of (1) to (3),

in which a relationship of R1_{mode}/R1ₘₐₓ≦0.9 is satisfied.

(5) The resin composition according to any one of (1) to (4),

in which the first particles having a particle diameter of 0.8R1_{mode} to 1.2R1_{mode} occupies 40% to 80% of the total volume of the inorganic filler.

(6) The resin composition according to anyone of (1) to (5),

in which a content of the inorganic filler is 50 mass % to 93 mass % with respect to the total mass of the resin composition.

(7) The resin composition according to any one of (1) to (6),

in which a gel time is 35 seconds to 80 seconds.

(8) The resin composition according to any one of (1) to (7),

in which the first particles are classified from a material containing the first particles and the second particles by sieving the material such that the second particles occupy 1% or less in the total volume of the inorganic filler.

(9) A semiconductor device including:

a substrate;

a semiconductor element that is provided over the substrate; and

a cured product of the resin composition according to any one of (1) to (8) that encapsulates the semiconductor element and fills a gap between the substrate and the semiconductor element.

### EXAMPLES

### Example 1

### Raw Materials

Hereinbelow, mixing amounts are shown in Table 1. In addition, characteristics of all the particles are shown in Table 2. In order to measure and evaluate a particle diameter distribution such as a mode diameter or a median diameter, a laser diffraction scattering particle diameter distribution analyzer SALD-7000 manufactured by Shimadzu Corporation was used. The same shall be applied to other examples and comparative examples.

[First Particles (Main Silica 1)]
Silica particles having a mode diameter of 16 μm and a maximum particle diameter of 24 μm (mode diameter/maximum particle diameter=0.67)

[Curing Resin]
NC-3000 manufactured by Nippon Kayaku Co., Ltd. (phenol aralkyl type epoxy resin having a biphenyl skeleton, epoxy equivalent: 276 g/eq, softening point: 57° C.)

[Curing Agent]
GPH-65 manufactured by Nippon Kayaku Co., Ltd. (phenol aralkyl type resin having a biphenylene skeleton, hydroxyl equivalent: 196 g/eq, softening point: 65° C.)

[Coupling Agent]
GPS-M manufactured by Chisso Corporation
   (γ-glycidoxypropyltrimethoxysilane)
S810 manufactured by Chisso Corporation
   (γ-mercaptopropyltrimethoxysilane)

[Curing Accelerator]
Curing accelerator 1 (curing accelerator represented by the following formula (5))

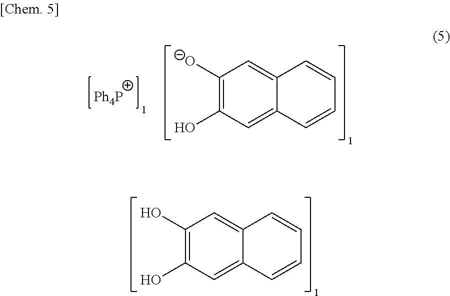

[Ion Scavenger]
DHT-4H (hydrotalcite) manufactured by Kyowa Chemical Industry Co., Ltd.

[Release Agent]
WE-4M (montanic acid ester wax) manufactured by Clariant Japan K.K.

[Flame Retardant]
CL-303 (aluminum hydroxide) manufactured by Sumitomo Chemical Co., Ltd.

[Colorant]
MA-600 (carbon black) manufactured by Mitsubishi Chemical Corporation

<Preparation of Resin Composition>

Using the above-described pulverizer 1 illustrated in FIG. 4, the above-described raw materials were pulverized.

Pressure of air supplied into the chamber: 0.7 MPa

Temperature of air supplied into the chamber: 3° C.

Humidity of air supplied into the chamber: 9% RH

Next, using a biaxial kneading extruder, the pulverized raw materials were kneaded under the following conditions.

Heating Temperature: 110° C.

Kneading Time: 7 minutes

Next, the kneaded product was degassed and cooled and then was pulverized using a pulverizer. As a result, a powdered resin composition was prepared. In an evaluation described below, optionally, using a tablet making machine, the powdered resin composition is compression-molded to prepare a table-like molded product.

### Example 2

A resin composition was prepared with the same method as Example 1, except that the material of the inorganic filler was changed as described below and shown in Table 1.

[Main Silica 1 (First Particles)]
Silica particles having a mode diameter of 16 μm and a maximum particle diameter of 24 μm (mode diameter/maximum particle diameter=0.67)

[Third Particles]
SO-25H (average particle diameter: 0.5 μm) manufactured by Adematechs

### Example 3

A resin composition was prepared with the same method as Example 1, except that the material of the inorganic filler was changed as described below and shown in Table 1.

[Main Silica 2 (First Particles)]
Silica particles having a mode diameter of 11 μm and a maximum particle diameter of 24 μm (mode diameter/maximum particle diameter=0.46)

### Example 4

A resin composition was prepared with the same method as Example 1, except that the material of the inorganic filler was changed as described below and shown in Table 1.

[Main Silica 3 (First Particles)]
Silica particles having a mode diameter of 10 μm and a maximum particle diameter of 18 μm (mode diameter/maximum particle diameter=0.56)

[Third Particles]
SO-25H (average particle diameter: 0.5 μm) manufactured by Adematechs

### Example 5

A resin composition was prepared with the same method as Example 1, except that the raw materials were changed as described below and shown in Table 1.

<Raw Materials>

[Main Silica 2 (First Particles)]
Silica particles having a mode diameter of 11 μm and a maximum particle diameter of 24 μm (mode diameter/maximum particle diameter=0.46)

[Third Particles]
SO-25H (average particle diameter: 0.5 μm) manufactured by Adematechs

[Curing Resin]
YL-6810 manufactured by Mitsubishi Chemical Corporation (bisphenol A type epoxy resin, epoxy equivalent: 170 g/eq, melting point: 47° C.)

[Curing Agent]
GPH-65 manufactured by Nippon Kayaku Co., Ltd. (phenol aralkyl type resin having a biphenylene skeleton, hydroxyl equivalent: 196 g/eq, softening point: 65° C.)

[Coupling Agent]
GPS-M manufactured by Chisso Corporation
   (γ-glycidoxypropyltrimethoxysilane)
S810 manufactured by Chisso Corporation
   (γ-mercaptopropyltrimethoxysilane)

[Curing Accelerator]
Curing accelerator 2 (curing accelerator represented by the following formula (6))

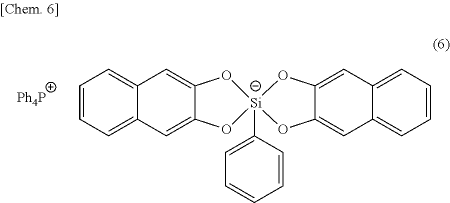 [SMILES: "Ph4P" ; c1ccc([Si-]23(Oc4cc5ccccc5cc4O2)Oc2cc4ccccc4cc2O3)cc1]

[Ion Scavenger]
DHT-4H manufactured by Kyowa Chemical Industry Co., Ltd.

[Release Agent]
WE-4M (montanic acid ester wax) manufactured by Clariant Japan K.K.

[Flame Retardant]
CL-303 (aluminum hydroxide) manufactured by Sumitomo Chemical Co., Ltd.

[Colorant]
MA-600 (carbon black) manufactured by Mitsubishi Chemical Corporation: 0.30 parts by mass

### Example 6

A resin composition was prepared with the same method as Example 1, except that the raw materials were changed as described below and shown in Table 1.

<Raw Materials>

[Main Silica 4 (First Particles)]
Silica particles having a mode diameter of 5 μm and a maximum particle diameter of 10 μm (mode diameter/maximum particle diameter=0.5)

[Third Particles]
SO-25H (average particle diameter: 0.5 μm) manufactured by Adematechs

[Curing Resin]
NC-3000 manufactured by Nippon Kayaku Co., Ltd. (phenol aralkyl type epoxy resin having a biphenyl skeleton, epoxy equivalent: 276 g/eq, softening point: 57° C.)
YL-6810 manufactured by Mitsubishi Chemical Corporation (bisphenol A type epoxy resin, epoxy equivalent: 170 g/eq, melting point: 47° C.)

[Curing Agent]
GPH-65 manufactured by Nippon Kayaku Co., Ltd. (phenol aralkyl type resin having a biphenylene skeleton, hydroxyl equivalent: 196 g/eq, softening point: 65° C.)
XLC-4L manufactured by Mitsui Chemicals Inc. (phenol aralkyl type resin having a phenylene skeleton, hydroxyl equivalent: 165 g/eq, softening point: 65° C.)

### Comparative Example 1

A resin composition was prepared with the same method as Example 1, except that the inorganic filler was changed as described below and shown in Table 1.

[Main Silica 5 (First Particles)]
Silica particles having a mode diameter of 10 μm and a maximum particle diameter of 24 μm (mode diameter/maximum particle diameter=0.42)

### Comparative Example 2

A resin composition was prepared with the same method as Example 1, except that the inorganic filler was changed as described below and shown in Table 1.

[Main Silica 5 (First Particles)]
Silica particles having a mode diameter of 10 μm and a maximum particle diameter of 24 μm (mode diameter/maximum particle diameter=0.42)

[Third Particles]
SO-25H (average particle diameter: 0.5 μm) manufactured by Adematechs

### Comparative Example 3

A resin composition was prepared with the same method as Example 5, except that the inorganic filler was changed as described below and shown in Table 1.

[Main Silica 6 (First Particles)]
Silica particles having a mode diameter of 9 μm and a maximum particle diameter of 24 μm (mode diameter/maximum particle diameter=0.38)

### Comparative Example 4

A resin composition was prepared with the same method as Example 6, except that the inorganic filler was changed as described below and shown in Table 1.

[Main Silica 7 (First Particles)]
Silica particles having a mode diameter of 4 μm and a maximum particle diameter of 10 μm (mode diameter/maximum particle diameter=0.4)

[Third Particles]
SO-25H (average particle diameter: 0.5 μm) manufactured by Adematechs

[Evaluation]

Each of the resin compositions of Examples 1 to 6 and Comparative Examples 1 to 4 was evaluated. The results are as shown in Table 1 below.

(Spiral Flow)

Using a low-pressure transfer molding machine (KTS-15, manufactured by KOHTAKI Corporation), a mold for measuring spiral flow according to ANSI/ASTM D 3123-72 was injected under conditions of a mold temperature of 175° C., an injection pressure of 6.9 MPa, and a holding time of 120 seconds to measure a spiral flow length thereof. The spiral flow is a parameter for fluidity, and the higher numerical value thereof, the higher the fluidity.

(Gel Time (Curability))

The resin composition was placed on a heating plate in which the temperature is controlled to 175° C. and was kneaded using a spatula at a stroke of about 1 time/sec. The time was measured until the resin composition was cured after being melted by heat, and the measured time was set as a gel time. The less numerical value of the gel time, the higher curing speed.

(Koka-Type Flow Viscosity)

Using a flow tester CFT-500c manufactured by Shimadzu Corporation), the apparent viscosity η of the molten resin composition was measured under test conditions of a temperature of 175° C., a load of 40 kgf (piston area: 1 cm²), a die hole diameter of 0.50 mm, and a die length of 1.00 mm. This apparent viscosity η was calculated from the following calculation expression. Q refers to the flow rate of the resin composition flowing per unit time. In addition, the less numerical value of the Koka-type flow viscosity, the lower viscosity.

η=(4ρDP/128LQ)×10⁻³ (Pa·sec)

η is apparent viscosity

D: die hole diameter (mm)

P: test pressure (Pa)

L: die length (mm)

Q: flow rate (cm³/sec)

(Filling Ability)

A flip-chip BGA (substrate: 0.36 mm-thick bismaleimide triazine resin/glass cloth substrate, package size: 16×16 mm, chip size: 10×10 mm, gap between substrate and chip: three gaps of 70 μm, 40 μm, and 30 μm, bump gap: 200 μm) was encapsulated and molded using a low-pressure transfer molding machine (Y series manufactured by TOWA) under conditions of a mold temperature of 175° C., an injection pressure of 6.9 MPa, and a curing time of 120 seconds. The filling ability of the resin composition regarding the gap between the substrate and the chip was observed using a ultrasonic flow detector (My Scorpe manufactured by Hitachi Construction Machinery Co., Ltd.).

In the item “Filling Ability” of Table 1, in all the cases where the gaps between the substrate and the chip were 70 μm, 40 μm, and 30 μm, “Superior” was determined when the resin composition was filled without voids being formed between the substrate and the chip. In all the cases where the gaps between the substrate and the chip were 70 μm, 40 μm, and 30 μm, “Unfilled” was determined when it was determined that areas (voids) where the resin composition did not fill a gap between the substrate and the chip were detected.

(Rectangular Pressure (Viscosity))

Using a low-pressure transfer molding machine (40 t manual press manufactured by NEC Corporation), the resin composition was injected into a rectangular flow channel formed of the mold and having a width of 13 mm, a height of 1 mm, and a length of 175 mm under conditions of a mold temperature of 175° C. and an injection speed of 177 cm³/sec, a pressure change over time is measured using a pressure sensor buried in a position of the flow channel which is distant from an upstream end by 25 mm, and a minimum pressure during the flowing of the resin composition was measured. The rectangular pressure is a parameter for melt viscosity, and the less numerical value, the lower and superior melt viscosity. When the value of the rectangular pressure is less than or equal to 6 MPa, there is no problem. When the value of the rectangular pressure is less than or equal to 5 MPa, superior viscosity can be obtained.

TABLE 1

| | | | Example 1 | Example 2 | Example 3 | Example 4 | Example 5 |
|---|---|---|---|---|---|---|---|
| First | Main Silica 1 | Part(s) by | 82.20 | 72.20 | | | |
| Particles | | Mass | | | | | |
| | Main Silica 2 | Part(s) by | | | 82.20 | | 74.16 |
| | | Mass | | | | | |
| | Main Silica 3 | Part(s) by | | | | 72.20 | |
| | | Mass | | | | | |
| | Main Silica 4 | Part(s) by | | | | | |
| | | Mass | | | | | |
| | Main Silica 5 | Part(s) by | | | | | |
| | | Mass | | | | | |
| | Main Silica 6 | Part(s) by | | | | | |
| | | Mass | | | | | |
| | Main Silica 7 | Part(s) by | | | | | |
| | | Mass | | | | | |
| Third | SO-25H | Part(s) by | | 10.00 | | 10.00 | 15.00 |
| Particles | | Mass | | | | | |
| Curing | NC-3000 | Part(s) by | 8.33 | 8.33 | 8.33 | 8.33 | |
| Resin | | Mass | | | | | |
| | YL-6810 | Part(s) by | | | | | 3.20 |
| | | Mass | | | | | |
| Curing | GPH-65 | Part(s) by | 5.52 | 5.52 | 5.52 | 5.52 | 3.69 |
| agent | | Mass | | | | | |
| | XLC-4L | Part(s) by | | | | | |
| | | Mass | | | | | |
| Coupling | GPS-M | Part(s) by | 0.20 | 0.20 | 0.20 | 0.20 | 0.20 |
| Agent | | Mass | | | | | |
| | S810 | Part(s) by | 0.20 | 0.20 | 0.20 | 0.20 | 0.20 |
| | | Mass | | | | | |
| Curing Accelerator 1 | | Part(s) by | 0.30 | 0.30 | 0.30 | 0.30 | |
| | | Mass | | | | | |
| Curing Accelerator 2 | | Part(s) by | | | | | 0.30 |
| | | Mass | | | | | |
| DHT-4H | | Part(s) by | 0.15 | 0.15 | 0.15 | 0.15 | 0.15 |
| | | Mass | | | | | |
| WE-4M | | Part(s) by | 0.30 | 0.30 | 0.30 | 0.30 | 0.30 |
| | | Mass | | | | | |
| CL-303 | | Part(s) by | 2.50 | 2.50 | 2.50 | 2.50 | 2.50 |
| | | Mass | | | | | |
| MA-600 | | Part(s) by | 0.30 | 0.30 | 0.30 | 0.30 | 0.30 |
| | | Mass | | | | | |
| First | Mode Diameter | μm | 16 | 16 | 11 | 10 | 11 |
| Particles | Maximum | μm | 24 | 24 | 24 | 18 | 24 |
| | Particle Diameter | | | | | | |
| | Mode Diameter/Maximum | | 0.67 | 0.67 | 0.46 | 0.56 | 0.46 |
| | Particle Diameter | | | | | | |
| | Median Diameter | μm | 12 | 12 | 8 | 8 | 8 |
| Third | Average | | | 0.5 | | 0.5 | 0.5 |
| Particles | Particle Diameter | | | | | | |
| Evaluation | Spiral Flow | cm | 92 | 96 | 87 | 91 | 92 |
| | Gel Time | sec | 45 | 43 | 46 | 48 | 36 |
| | Koka-Type Flow | Pa · sec | 25.8 | 24.7 | 26.1 | 25.4 | 16.9 |
| | Viscosity | | | | | | |
| | Filling Ability | | Superior | Superior | Superior | Superior | Superior |
| | Rectangular Pressure | MPa | 4.3 | 4.1 | 4.6 | 4.5 | 3.3 |

| | | | | Comparative | Comparative | Comparative | Comparative |
|---|---|---|---|---|---|---|---|
| | | | Example 6 | Example 1 | Example 2 | Example 3 | Example 4 |
| First | Main Silica 1 | Part(s) by | | | | | |
| Particles | | Mass | | | | | |
| | Main Silica 2 | Part(s) by | | | | | |
| | | Mass | | | | | |
| | Main Silica 3 | Part(s) by | | | | | |
| | | Mass | | | | | |
| | Main Silica 4 | Part(s) by | 67.85 | | | | |
| | | Mass | | | | | |
| | Main Silica 5 | Part(s) by | | 82.20 | 72.20 | | |
| | | Mass | | | | | |
| | Main Silica 6 | Part(s) by | | | | 74.16 | |
| | | Mass | | | | | |
| | Main Silica 7 | Part(s) by | | | | | 67.85 |
| | | Mass | | | | | |
| Third | SO-25H | Part(s) by | 15.00 | | 10.00 | 15.00 | 15.00 |
| Particles | | Mass | | | | | |
| Curing | NC-3000 | Part(s) by | 3.08 | 8.33 | 8.33 | | 3.08 |
| Resin | | Mass | | | | | |
| | YL-6810 | Part(s) by | 4.29 | | | 3.20 | 4.29 |
| | | Mass | | | | | |
| Curing | GPH-65 | Part(s) by | 1.85 | 5.52 | 5.52 | 3.69 | 1.85 |
| agent | | Mass | | | | | |
| | XLC-4L | Part(s) by | 3.98 | | | | 3.98 |
| | | Mass | | | | | |
| Coupling | GPS-M | Part(s) by | 0.20 | 0.20 | 0.20 | 0.20 | 0.20 |
| Agent | | Mass | | | | | |
| | S810 | Part(s) by | 0.20 | 0.20 | 0.20 | 0.20 | 0.20 |
| | | Mass | | | | | |
| Curing Accelerator 1 | | Part(s) by | 0.30 | 0.30 | 0.30 | | 0.30 |
| | | Mass | | | | | |
| Curing Accelerator 2 | | Part(s) by | | | | 0.30 | |
| | | Mass | | | | | |
| DHT-4H | | Part(s) by | 0.15 | 0.15 | 0.15 | 0.15 | 0.15 |
| | | Mass | | | | | |
| WE-4M | | Part(s) by | 0.30 | 0.30 | 0.30 | 0.30 | 0.30 |
| | | Mass | | | | | |
| CL-303 | | Part(s) by | 2.50 | 2.50 | 2.50 | 2.50 | 2.50 |
| | | Mass | | | | | |
| MA-600 | | Part(s) by | 0.30 | 0.30 | 0.30 | 0.30 | 0.30 |
| | | Mass | | | | | |
| First | Mode Diameter | μm | 5 | 10 | 10 | 9 | 4 |
| Particles | Maximum | μm | 10 | 24 | 24 | 24 | 10 |
| | Particle Diameter | | | | | | |
| | Mode Diameter/Maximum | | 0.5 | 0.42 | 0.42 | 0.38 | 0.40 |
| | Particle Diameter | | | | | | |
| | Median Diameter | μm | 3 | 10 | 10 | 8 | 3 |
| Third | Average | | 0.5 | | 0.5 | 0.5 | 0.5 |
| Particles | Particle Diameter | | | | | | |
| Evaluation | Spiral Flow | cm | 88 | 67 | 70 | 66 | 62 |
| | Gel Time | sec | 46 | 39 | 37 | 31 | 48 |
| | Koka-Type Flow | Pa · sec | 31.4 | 35.0 | 48.5 | 42.1 | 55.2 |
| | Viscosity | | | | | | |
| | Filling Ability | | Superior | Unfilled | Unfilled | Unfilled | Unfilled |
| | Rectangular Pressure | MPa | 4.8 | 4.8 | 6.1 | 5.4 | 5.5 |

TABLE 2

| | | | | | | | Compara- | Compara- | Compara- | Compara- |
|---|---|---|---|---|---|---|---|---|---|---|
| | | | | | | | tive | tive | tive | tive |
| | Exam- | Exam- | Exam- | Exam- | Exam- | Exam- | Example | Example | Example | Example |
| All Particles | ple 1 | ple 2 | ple 3 | ple 4 | ple 5 | ple 6 | 1 | 2 | 3 | 4 |
| R(μm) | 16 | 16 | 11 | 10 | 11 | 5 | 10 | 10 | 9 | 4 |
| Rₘₐₓ(μm) | 24 | 24 | 24 | 18 | 24 | 10 | 24 | 24 | 24 | 10 |
| d₅₀(μm) | 12 | 9.5 | 8 | 7.8 | 5.1 | 1.07 | 10 | 8.6 | 4.2 | 1.2 |
| R/Rₘₐₓ | 0.67 | 0.67 | 0.46 | 0.56 | 0.46 | 0.50 | 0.42 | 0.42 | 0.38 | 0.40 |
| R/d₅₀ | 1.33 | 1.68 | 1.38 | 1.28 | 2.16 | 4.67 | 1.00 | 1.16 | 2.14 | 3.33 |
| Frequency (%) of Particles | 6.85 | 6.01 | 5.48 | 6.30 | 5.10 | 4.52 | 8.93 | 7.84 | 5.54 | 3.82 |
| having Particle Diameter | | | | | | | | | | |
| of R(μm) | | | | | | | | | | |
| Frequency (%) of Particles | 32.67 | 28.70 | 24.79 | 29.20 | 23.07 | 21.41 | 40.19 | 35.30 | 25.54 | 18.28 |
| having Particle Diameter | | | | | | | | | | |
| of 0.8R to 1.2R (μm) | | | | | | | | | | |
| R/G(gap = 30 μm) | 0.53 | 0.53 | 0.37 | 0.33 | 0.37 | 0.17 | 0.33 | 0.33 | 0.30 | 0.13 |
| R/G(gap = 40 μm) | 0.40 | 0.40 | 0.28 | 0.25 | 0.28 | 0.13 | 0.25 | 0.25 | 0.23 | 0.10 |
| R/G(gap = 70 μm) | 0.23 | 0.23 | 0.16 | 0.14 | 0.16 | 0.07 | 0.14 | 0.14 | 0.13 | 0.06 |

As clearly seen from Table 1, sine the inorganic filler according to the present invention was used in Examples 1 to 6, superior fluidity (spiral flow) and filling ability were obtained. In particular, superior filling ability was exhibited in the semiconductor device having a narrow gap of 30 μm or 40 μm and showing a specific flow behavior in which filling is difficult. On the other hand, in the comparative examples, the following was found. In a case where the gap between the substrate and the chip was particularly narrow at 40 μm or 30 μm, even when the maximum particle diameter was less than the gap between the substrate and the chip, a phenomenon of unfilling increased, and thus the problems caused by not only general fluidity but the above-described specific flow resistance were not able to be solved. That is, in the concept of an inorganic filler in which a median diameter of the related art is designed, it was found that superior filling ability cannot be obtained in a so-called mold underfill in which, when a semiconductor chip is encapsulated with a resin composition, the resin composition fills a gap between a circuit substrate and a semiconductor for reinforcement.

Priority is claimed on Japanese Patent Application No. 2012-077658 filed on Mar. 29, 2012, the content of which is incorporated herein by reference.

1. A resin composition for encapsulation comprising:
a curing resin (B); and
an inorganic filler (C),
wherein the resin composition encapsulates a semiconductor element provided over a substrate and fills a gap between the substrate and the semiconductor element, and
when a particle diameter at a cumulative frequency of 5% in order from the largest particle diameter in a volume particle diameter distribution of particles contained in the inorganic filler (C) is represented by Rₘₐₓ (μm),
and when a maximum peak diameter in the volume particle diameter distribution of the particles contained in the inorganic filler (C) is represented by R (μm),
R<Rₘₐₓ,
1 μm≦R≦24 μm, and
R/Rₘₐₓ≧0.45.

2. The resin composition according to claim 1,
wherein a particle diameter at a cumulative frequency of 50% in order from the smallest particle diameter in the volume particle diameter distribution of the particles contained in the inorganic filler (C) is represented by d₅₀ (μm),
R/d₅₀ is more than or equal to 1.1 and less than or equal to 15.

3. The resin composition according to claim 1,
wherein a frequency of particles having the particle diameter of R (μm) is higher than or equal to 4% in the volume particle diameter distribution of the particles contained in the inorganic filler (C).

4. The resin composition according to claim 1,
wherein a spiral flow length which is measured when a mold for measuring spiral flow according to ANSI/ASTM D 3123-72 is injected under conditions of a mold temperature of 175° C., an injection pressure of 6.9 MPa, and a holding time of 120 seconds is more than or equal to 70 cm, and
a pressure A which is measured under the following conditions is less than or equal to 6 MPa:
(Conditions)
under conditions of a mold temperature of 175° C. and an injection speed of 177 cm³/sec, the resin composition is injected into a rectangular flow channel formed of the mold and having a width of 13 mm, a height of 1 mm, and a length of 175 mm, a pressure change over time is measured using a pressure sensor buried in a position of the flow channel which is distant from an upstream end by 25 mm, and a minimum pressure during the flowing of the resin composition is set as the pressure A.

5. The resin composition according to claim 1,
wherein when the gap between the substrate and the semiconductor element is represented by G (μm),
R/G is more than or equal to 0.05 and less than or equal to 0.7.

6. The resin composition according to claim 1,
wherein particles having a particle diameter of 0.8×R (μm) to 1.2×R (μm) occupy 10% to 60% of the total volume of the inorganic filler (C).

7. The resin composition according to claim 1,
wherein a content of the inorganic filler (C) is 50 mass % to 93 mass % with respect to the total mass of the resin composition.

8. The resin composition according to claim 1,
wherein the particles are obtained by raw material particles being classified through a sieve.

9. A semiconductor device comprising:
a substrate;
a semiconductor element that is provided over the substrate; and
a cured product of the resin composition according to claim 1 that coats the semiconductor element to be encapsulated and fills a gap between the substrate and the semiconductor element.

10. A resin composition comprising:
a curing resin (B); and
an inorganic filler,
wherein the resin composition encapsulates s semiconductor element provided over a substrate and fills a gap between the substrate and the semiconductor element during the encapsulation,
the resin composition is obtained by mixing first particles (C1) contained in the inorganic filler and the curing resin (B),
the first particles (C1) have a maximum particle diameter of R1ₘₐₓ (μm), and when a mode diameter of the first particles (C1) is represented by R1_{mode} (μm), a relationship of 4.5 μm≦R1_{mode}≦24 μm and a relationship of R1_{mode}/R1ₘₐₓ≧0.45 are satisfied.

11. The resin composition according to claim 10,
wherein R1ₘₐₓ (μm) is 24 (μm), and
R1_{mode}≦20 μm.

12. The resin composition according to claim 10,
wherein a relationship of R1_{mode}/R1ₘₐₓ≦0.9 is satisfied.

13. The resin composition according to claim 10,
wherein the first particles (C1) having a particle diameter of 0.8R1_{mode} to 1.2R1_{mode} are added in an amount of 10% to 60% with respect to the total volume of the inorganic filler.

14. The resin composition according to claim 10,
wherein a content of the inorganic filler is 50 mass % to 93 mass % with respect to the total mass of the resin composition.

15. The resin composition according to claim 10,
wherein a gel time is 35 seconds to 80 seconds.

16. A semiconductor device comprising:
a substrate;
a semiconductor element that is provided over the substrate; and
a cured product of the resin composition according to claim 10 that encapsulates the semiconductor element and fills a gap between the substrate and the semiconductor element.
